(19) United States
(12) Patent Application Publication
(10) Pub. No.: US 2026/0177606 A1
(43) Pub. Date: Jun. 25, 2026

(54) WAFER-LEVEL BURN-IN TEST FIXTURE, TEST DEVICE, METHOD, AND SYSTEM

(71) Applicant: SEMIGHT INSTRUMENTS CO., LTD, Suzhou (CN)

(72) Inventors: Renwei TANG, Suzhou (CN); Bin ZHOU, Suzhou (CN); Xiaoming GUO, Suzhou (CN); Zhe LIAN, Suzhou (CN); Jianjun HUANG, Suzhou (CN); Haiyang HU, Suzhou (CN)

(21) Appl. No.: 18/851,686

(22) PCT Filed: Jun. 18, 2024
(86) PCT No.: PCT/CN2024/099870

§ 371 Date: Sep. 27, 2024

(30) Foreign Application Priority Data
Feb. 8, 2024 (CN) 202410178868.4
Feb. 8, 2024 (CN) 202410179074.X
Feb. 8, 2024 (CN) 202410179076.9
Feb. 8, 2024 (CN) 202420292036.0

(51) Int. Cl. G01R 31/28; G01R 1/04

(52) U.S. Cl. CPC G01R 31/2863; G01R 1/0416; G01R 31/2867; G01R 31/2875

(57) ABSTRACT

A wafer-level burn-in test fixture, test device, method, and system, relating to the technical field of wafer testing. The wafer-level burn-in test device includes the wafer-level burn-in test fixture and a lifting structure. The wafer-level burn-in test fixture includes a cover plate assembly, a lower sealing assembly, a heat sink, and a heating device. The heat sink is used to carry a wafer. The cover plate assembly includes a first PCB and a test probe holder connected to the first PCB. The lower sealing assembly includes a lower sealing cover. The lower sealing cover and the cover plate assembly are connected to form a test chamber. The heat sink and heating device are in the test chamber. The heating device is between the lower sealing cover and the heat sink. The lifting structure is configured to extend up and down in a controlled manner. The lifting structure abuts the wafer-level burn-in test fixture in a movable manner to drive the lower sealing assembly to move upward and connect with the cover plate assembly to form the test chamber.

### TECHNICAL FIELD

The present invention relates to the field of wafer testing technology and, more particularly, relates to a wafer-level burn-in test fixture, wafer-level burn-in test device, test method, and test system.

### BACKGROUND

In the field of wafer-level burn-in test, wafers need to be placed in a sealed test chamber for high-pressure and high-temperature testing. In the existing technology, a PCB and a lower sealing cover are usually connected to form a sealed test chamber directly, and then a wafer in the lower sealing cover is tested under high pressure and high temperature. With technical solutions for high-temperature and high-pressure wafer testing in the lower sealing cover, the PCB and lower sealing cover are lowered together to a position to cooperate with a heating device, and then high-temperature tests on the wafer in the lower sealing cover are performed. The method does not cause excessive pressure on the PCB. However, during testing on 8-inch wafers, because the wafer has a large size and is prone to curl and deform in a high-temperature and high-pressure testing environment, high-temperature and high-pressure test results of wafers are affected. In addition, the required pressure to close a test chamber for 8-inch wafers is relatively large. If it is not closed tightly, breakdown can happen to a wafer. Due to the large area of an 8-inch wafer during wafer-level burn-in tests, the wafer is prone to curl and deform in a high-temperature and high-pressure environment. It affects results of wafer-level burn-in testing. Thus, a better fixation method is needed. For example, a PCB and a lower sealing cover can be separated and forces can be applied in the upward and downward directions for fixation. It can press a wafer tightly to avoid curling and deformation of the wafer. But there is no such method in the current technology. During a pressing process of the current technique, if a PCB is pressed too much, the PCB can deform and no contact or poor contact can occur between a test probe and a wafer, which causes test errors.

In the existing technology, a probe is used to connect a PCB with an external test device. The connection is a rigid connection, which has high requirements on positions and structures of the PCB and external test device. Further, there is a high degree of correlation between structures of an external test device and a fixture. The positions are fixed, it is relatively complex to install and maintain, and it lacks flexibility in structural layout. In addition, there are multiple contact points between a probe and a PCB for a circuit and the probe has a limited service life. When any probe is damaged, it affects the connection between the PCB and external test device, and even directly affects the service life of the PCB and external test device. The reliability and stability can be reduced. When one end of a probe contacts a contact point on a surface of a fixture and the other end of the probe is directly connected to an external test device, it has high requirements for structural machining and installation accuracy, and sizes of related structures are limited. The size of wafers accommodated by a fixture is relatively small. The number of channels that can be powered on is also relatively small.

During wafer-level burn-in testing, power-on tests and tests at elevated temperatures are usually performed to get wafer-level burn-in performance of a wafer. For tests at elevated temperatures, a heating device is used to heat up a wafer for testing high-temperature resistance of the wafer. In the current technology, a heating device is usually positioned at the bottom of a lower sealing cover. The lower sealing cover is heated by multiple heating plates for performing high-temperature test on a wafer in the lower sealing cover. However, heating through multiple heating plates can cause uneven heating of the wafer. Further, since the heating device is placed outside the lower sealing cover, the heat transfer rate is low and wafer testing efficiency is affected.

### CONTENT OF THE INVENTION

An object of one aspect of the invention is to provide a wafer-level burn-in test device that prevents wafers from curling in a high-temperature and high-pressure testing environment.

A further object of one aspect of the invention is to improve the wafer burn-in test accuracy of a wafer-level burn-in test device.

Another further object of one aspect of the invention is to optimize the structure of a wafer-level burn-in test device.

An object of another aspect of the invention is to provide a wafer-level burn-in test system including the above-mentioned wafer-level burn-in test device.

An object of an additional aspect of the invention is to provide a test method for the above-mentioned wafer-level burn-in test device.

An object of another aspect of the invention is to provide a wafer-level burn-in test fixture to solve technical problems including that the probe connection method in the existing technology leads to a small number of power-on channels.

A further object of another aspect of the invention is to avoid deformation of a test probe holder and a connector due to thermal expansion.

An even further object of another aspect of the invention is to avoid damaging a PCB when a pressing force in a test chamber is large.

An object of yet another aspect of the invention is to provide a wafer-level burn-in test fixture to solve technical problems including uneven wafer heating at high-temperature burn-in tests.

Another object of yet another aspect of the invention is to simplify the structure of a heating device.

Another object of yet an additional aspect of the invention is to avoid damaging a wafer by avoiding direct contact between a heating device and the wafer through configuring a ceramic plate's position reasonably.

In particular, based on an aspect, the invention provides a wafer-level burn-in test device that includes:
A wafer-level burn-in test fixture that includes a cover plate assembly, a lower sealing assembly, a heat sink, and a heating structure, wherein the heat sink is used to carry a wafer; the cover plate assembly includes a first PCB and a test probe holder connected to the first PCB; the lower sealing assembly includes a lower sealing cover, and the lower sealing cover is connected with the cover plate assembly to form a test chamber; the heat sink and the heating device are disposed in the test chamber; and the heating device is placed between the lower sealing cover and the heat sink; and
A lifting structure, wherein the lifting structure is configured to extend up and down in a controlled manner, and the lifting structure abuts the wafer-level burn-in test fixture in a movable manner to drive the lower sealing assembly to move upward and connect with the cover plate assembly to form the testing chamber.

Optionally, the wafer-level burn-in test device further includes:
A mounting bracket that includes a top plate assembly and a bottom plate assembly, wherein the top plate assembly and bottom plate assembly are connected by a pillar, the wafer-level burn-in test fixture is arranged below the top plate assembly and connected to the top plate assembly, and the lifting structure is mounted on the bottom plate assembly; and a floating structure, wherein the floating structure is arranged at the top plate assembly, the floating structure is configured to float when the cover plate assembly is pressed by the lower sealing cover, thereby avoiding deformation of the cover plate assembly.

In particular, based on another aspect, the invention provides a wafer-level burn-in test system that includes a loading and unloading device, at least one test device, and at least one wafer-level burn-in test device as illustrated above;

The loading and unloading device is used to place a wafer in a corresponding wafer-level burn-in test device for performing wafer-level burn-in tests;

Any wafer-level burn-in test device is connected to a corresponding test device for wafer-level burn-in testing.

In particular, based on yet another aspect, the invention provides a method for the aforementioned wafer-level burn-in test device. The method includes the following steps:
After wafer loading is completed, controlling a lifting structure to rise upward to a first height and causing the lifting structure to connect with a lower sealing assembly;
Controlling the lifting structure to continue to drive the lower sealing assembly upward to a second height and causing the lower sealing assembly to move to connect with the cover plate assembly to form a test chamber; and
Powering up a heating device, a heat sink, and a test probe holder included in the cover plate assembly and performing wafer-level burn-in testing on wafers.

In particular, based on another aspect, the invention also provides a wafer-level burn-in test fixture that contains a cover plate assembly and a lower sealing assembly. The cover plate assembly and lower sealing assembly are connected to form a test chamber for accommodating a wafer.

Optionally, the cover plate assembly includes a PCB, wherein the PCB contains a first area and a second area respectively located on different sides of the PCB, and any first contact point provided in the first area is electrically connected to a corresponding second contact point provided in the second area; a test probe holder, wherein the test probe holder is positioned at the bottom of the PCB, connected to the PCB, and has multiple test probes, one end of any test probe is in contact with a corresponding first contact, and the other end is in contact with a wafer for performing wafer-level burn-in testing on the wafer; and at least one connector wherein the connector is mounted in the second area of the PCB, and any connector is connected to a corresponding second contact point, connected to an external test device via a wiring harness, and used for wafer-level burn-in testing of the wafer.

Optionally, the wafer-level burn-in test fixture further includes a heat sink for carrying a wafer and a heating device. The heat sink and heating device are in the test chamber. The heat sink is stacked above the heating device. The heating device is electrically connected to an electrical component located below the lower sealing assembly. The heating device includes:

A heating film layer, wherein the heating film layer contains uniformly arranged resistance wires and at least one power interface connected to the resistance wires, and the heating film layer is disposed on a side of the heat sink away from the wafer and heats up the wafer through the heat sink; and a connection assembly, wherein the connection assembly contains at least one first connection probe set that passes through the lower sealing assembly, one end of any first connection probe set is in contact with a corresponding power interface, and the other end passes through the lower sealing assembly and contacts the electrical component, so that the electrical component may supply power and heat up the heating film layer.

Based on some aspects of the invention, a heating device is set in a lower sealing cover, a wafer is placed on a heat sink, and a lifting structure extends up and down. The lifting structure drives the lower sealing assembly to move upward and connect with a cover plate assembly to form a test chamber and press the heat sink tightly. As the hest sink is flat, the wafer is flat and does not curl. The wafer is pressed tightly to avoid breakdown of the wafer.

Further, the lifting structure includes a lifting component and an electrical component. After the lifting structure drives the lower sealing assembly to move upward to connect with the cover plate assembly, the electrical component of the lifting structure is used to power the heating device and heat sink in the test chamber. That is, the lifting structure is used to press the wafer tightly by a lifting act and power up the heating device and heat sink. Thus, the structure of the wafer-level burn-in test device is optimized.

Based on some other aspects of the invention, a floating structure is provided at a top plate assembly of a mounting bracket. The floating structure is configured to float when the cover plate assembly is pressed by the lower sealing cover, so that deformation of the cover plate assembly under pressure is avoided. It ensures that a test probe on the cover plate assembly is in contact with the wafer. Contact stability is improved and thus the accuracy of wafer-level burn-in testing is improved.

Further, during a lifting process of the lifting structure, cooperation of a Pad on the top of a second PCB of the electrical component and a lower sealing cover is used to power the heating device and heat sink. High-pressure and high-temperature tests on wafers are realized. As such, the lifting structure not only presses a wafer tightly by lifting, but also provides test conditions for the wafer in the lower sealing cover. The structure of the wafer-level burn-in test device is optimized.

Based on additional aspects of the invention, a connector is added in a second area of the PCB and a wire harness is used to connect the connector with an external test device. The method of using probe connection in the existing technology is cancelled. That is, rigid connection is replaced by flexible connection. Thus, relative positions of the wafer-level burn-in test fixture and external test device may be flexibly arranged separately. The number of channels powering a wafer may be increased. In addition, when probes are used to connect to an external test device, there are many contact points, which results in lower reliability of circuit connections. In the invention, wire harness connection is used and there are no contact points. Hence, the reliability of circuit connection is improved.

Further, in the invention, at least one groove is provided on the edge of the test probe holder. A supporting portion of a connector is provided with at least one positioning post. Each positioning post is arranged corresponding to a groove to position the test probe holder. The cooperation between of the positioning post and the groove defines the position of the test probe holder. The groove is not closed. The positioning post only contacts two sides of the groove along the circumferential direction of the test probe holder. When the test probe holder and connector expand due to heat, the positioning post may slide a small amount in the groove along the radial direction of the test probe holder and does not press the groove. It eliminates the stress caused by expansion of the test probe holder and connector, and avoids deformation of the test probe holder and connector.

Further, in the invention, a load-bearing column that passes through the PCB is provided. One end of the load-bearing column is connected to the upper sealing cover on the top of the PCB, and the other end protrudes from the bottom surface of the PCB. When the pressing force in the test chamber is too large and the lower sealing cover is too close to the PCB, the load-bearing column contacts the lower sealing cover before the PCB, thereby withstanding the pressing force of the test chamber and preventing the PCB from being damaged by excessive pressure.

Based on additional embodiments of the invention, the heating device of the wafer-level burn-in test fixture includes a heating film layer and a connecting component. The heating film layer contains uniformly arranged resistance wires and at least one power interface connected to the resistance wires. The heating film layer is disposed on a side of the heat sink away from the wafer and heats up the wafer through the heat sink. The connecting component contains at least one first connection probe set that passes through the lower sealing assembly. One end of any first connection probe set is in contact with a corresponding power interface, while the other end passes through the lower sealing assembly and contacts the electrical component. As such, the electrical component supplies power to the heating film layer, and the heating film layer heats up the wafer on the heat sink. In the above technical solution, the heating film layer contains evenly arranged resistance wires, and the method using multiple heating sheets in the current technology is eliminated. Thus wafers are heated evenly and local overheating of wafers is avoided. Additionally, the heating device is disposed in the lower sealing assembly, which is equivalent to integrating the lower sealing assembly and heating device. Compared to current techniques where an auxiliary structure is needed to make the lower sealing assembly contact the heating device, the structure of wafer-level burn-in test device is simplified and the wafer heating efficiency by the heating device is improved. Thus, wafer testing efficiency is improved.

Further, in the invention, the heating film layer of the heating device has uniformly arranged resistance wires and at least one power interface connected to the resistance wires. The first connection probe set is directly connected to the resistance wires through the power interface, so that the heating film layer is heated uniformly. Setting up multiple probe sets corresponding to multiple heating plates is avoided. The structure of the heating device is simplified.

Further, the heating device also includes a ceramic plate. The ceramic plate is arranged between a second thermal insulation element and the heat sink, and used to transfer the heat generated by the heating film layer to the heat sink. It avoids damaging a wafer when the heating device contacts the wafer directly and reduces the defective rate of wafers during wafer-level burn-in tests.

From the following detailed description of embodiments of the invention in conjunction with the accompanying drawings, those skilled in the art may further understand the above and other objectives, advantages, and features of the invention.

### BRIEF DESCRIPTION OF THE DRAWINGS

Some specific embodiments of the present invention will be described in detail below by way of illustration and not limitation with reference to the accompanying drawings. The same reference numbers in the drawings identify the same or similar parts or portions. Those skilled in the art will appreciate that these drawings are not necessarily drawn to scale.

FIG. 1 is a schematic structural diagram of a wafer-level burn-in test device according to an embodiment of the invention;

FIG. 2 is a schematic structural diagram of a cover plate assembly in the wafer-level burn-in test device shown in FIG. 1;

FIG. 3 is a schematic cross-sectional view of a lower sealing cover of the wafer-level burn-in test device shown in FIG. 1;

FIG. 4 is a schematic enlargement of a part A in FIG. 3;

FIG. 5 is a schematic structural diagram of a lower sealing cover of the wafer-level burn-in test device shown in FIG. 1;

FIG. 6 is a schematic structural diagram of a lifting structure in the wafer-level burn-in test device shown in FIG. 1;

FIG. 7 is a schematic structural diagram of an adapter plate of the lifting structure shown in FIG. 6;

FIG. 8 is a schematic connection diagram of a wafer-level burn-in test system according to an embodiment of the invention;

FIG. 9 is a schematic flow chart of a test method for a wafer-level burn-in test device according to an embodiment of the invention;

FIG. 10 is a schematic structural diagram of a wafer-level burn-in test device according to an embodiment of the invention;

FIG. 11 is a schematic cross-sectional view of a floating structure and a top plate assembly in the wafer-level burn-in test device shown in FIG. 1;

FIG. 12 is a schematic enlarged view of a part A in FIG. 11;

FIG. 13 is a schematic structural diagram of a lower cover plate of the wafer-level burn-in test device shown in FIG. 10;

FIG. 14 is a schematic installation diagram of a floating plate and a lower cover plate of the wafer-level burn-in test device shown in FIG. 10;

FIG. 15 is a schematic structural diagram of an upper cover plate of the wafer-level burn-in test device shown in FIG. 10;

FIG. 16 is a schematic structural diagram of a lifting structure of the wafer-level burn-in test device shown in FIG. 10;

FIG. 17 is a schematic structural diagram of a wafer-level burn-in test fixture according to an embodiment of the invention;

FIG. 18 is a schematic exploded view of a wafer-level burn-in test fixture according to an embodiment of the invention;

FIG. 19 is a schematic location diagram of a wafer-level burn-in test fixture and an external test device according to an embodiment of the invention;

FIG. 20 is a schematic structural diagram of a PCB shown in FIG. 18;

FIG. 21 is a schematic structural diagram of a test probe holder according to an embodiment of the invention;

FIG. 22 is a schematic enlarged view of a part A in FIG. 21;

FIG. 23 is a schematic structural diagram of a connector according to an embodiment of the invention;

FIG. 24 is a schematic enlarged view of a part B in FIG. 23;

FIG. 25 is a schematic position diagram of a load-bearing component according to an embodiment of the invention;

FIG. 26 is a schematic structural diagram of the load-bearing component shown in FIG. 25;

FIG. 27 is a schematic structural diagram of a lifting structure according to an embodiment of the invention;

FIG. 28 is a schematic structural diagram of a heating device according to an embodiment of the invention;

FIG. 29 is a schematic cross-sectional diagram of a heating device according to an embodiment of the invention;

FIG. 30 is a schematic partial enlarged view of a part A shown in FIG. 29;

FIG. 31 is a schematic cross-sectional diagram of a heating device from another angle according to an embodiment of the invention;

FIG. 32 is a schematic partial enlarged view of a part B shown in FIG. 31;

FIG. 33 is a schematic structural diagram of a wafer-level burn-in test device according to an embodiment of the invention;

FIG. 34 is a schematic cross-sectional view of part of the structure of a wafer-level burn-in test device according to an embodiment of the invention; and

FIG. 35 is a schematic partial enlarged view of a part C shown in FIG. 34.

### DETAILED DESCRIPTION

The embodiments of the invention are described in detail below. Examples of the embodiments are illustrated in the drawings, wherein the same or similar reference numerals throughout represent the same or similar elements or elements having the same or similar functions. The embodiments described below with reference to the drawings are exemplary and intended to explain the invention and are not to be construed as limiting the present invention.

In describing the invention, it is to be understood that the orientation or positional relationship indicated by terms “upper”, “lower”, “left”, and “right” are based on the orientation or positional relationship shown in the drawings. The terms are used for describing the invention and simplifying descriptions, and not used for indicating or implying that a device or element referred to must have a particular orientation, or be constructed and operated in a particular orientation. The terms cannot be construed as limitations of the invention.

Terms “first” and “second” are used for descriptive purposes only and cannot be understood as indicating or implying relative importance or implicitly indicating the number of indicated technical features. Features defined as “first” and “second” may explicitly or implicitly include at least one of the features, that is, include one or more of the features. In the description of the invention, “multiple” means at least two, such as two, three, etc, unless otherwise expressly and specifically limited. When a certain feature “includes or comprises” one or more features it encompasses, unless specifically stated otherwise, this indicates that other features are not excluded and may further be included.

Unless otherwise expressly stated and limited, terms “connection”, “installation” are interpreted broadly. For example, it may be a fixed connection, a detachable connection, or an integrated body; a mechanical connection, or an electrical connection; directly connected or indirectly connected through an intermediary; or an internal connection between two components, or an interaction between two components, unless otherwise expressly limited. Those of ordinary skill in the art should be able to understand the specific meanings of the above terms in the invention according to specific circumstances.

Unless otherwise limited, all terms (including technical terms and scientific terms) used in descriptions of the embodiments have the same meanings as that commonly understood by those of ordinary skill in the technical field to which this application belongs.

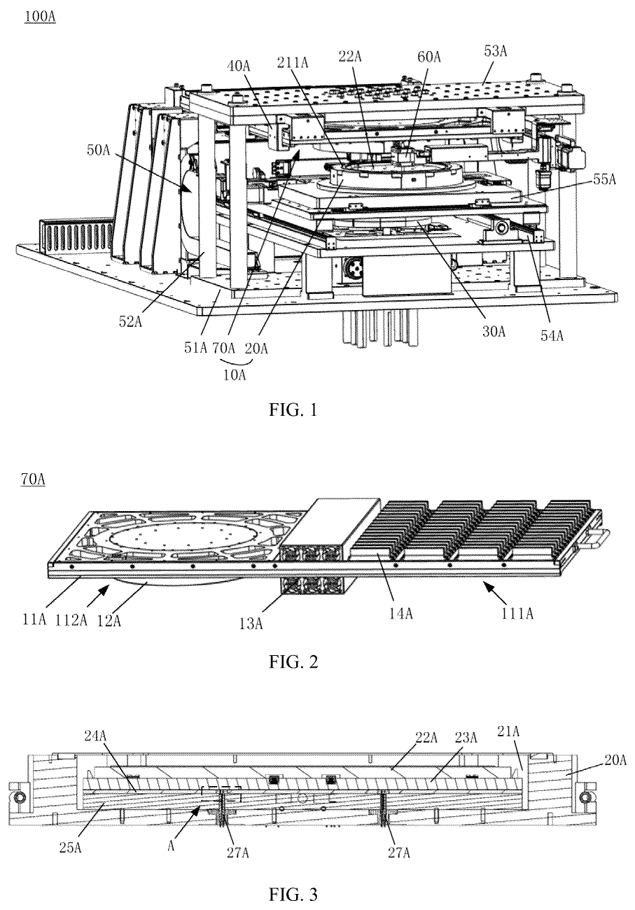

FIG. 1 is a schematic structural diagram of a wafer-level burn-in test device 100A according to an embodiment of the invention. FIG. 2 is a schematic structural diagram of a cover plate assembly 70A of the wafer-level burn-in test device 100A shown in FIG. 1. As shown in FIGS. 1 and 2, in the embodiment, the wafer-level burn-in test device 100A includes a wafer-level burn-in test fixture 10A and a lifting structure 30A. The wafer-level burn-in test fixture 10A includes the cover plate assembly 70A, a lower sealing assembly, a heat sink 22A, and a heating device. The heat sink 22A is used to carry a wafer. The cover plate assembly 70A includes a first PCB 11A and a test probe holder 12A connected to the first PCB 11A. The lower sealing assembly includes a lower sealing cover 20A. The lower sealing cover 20A is connected with the cover plate assembly 70A to form a test chamber 21A. The heat sink 22A and the heating device are disposed in the test chamber 21A. The heating device is between the lower sealing cover 20A and the heat sink 22A. The lifting structure 30A is configured to extend up and down in a controlled manner. The lifting structure 30A is connected to the wafer-level burn-in test fixture 10A in a movable manner, which is used to drive the lower sealing assembly to move upward and connect with the cover plate assembly 70A to form the test chamber 21A. The test probe holder 12A contains multiple test probes for testing wafers. The lower sealing cover 20A is located below the wafer-level burn-in test fixture 10A. When the lower sealing cover 20A and the cover plate assembly 70A form the test cavity 21A, the test probe holder 12A is in the test chamber 21A, which enables the test probes at the test probe holder 12A to be connected to the wafer for wafer-level burn-in testing.

In the embodiment, the heating device is arranged in the lower sealing cover 20A and the wafer is on the heat sink 22A. The lifting structure 30A, extending up and down, is utilized to drive the lower sealing assembly to move upward and connect with the cover plate assembly to form the test chamber 21A. The lifting structure 30A presses the heat sink 22A tightly. As the heat sink 22A is flat, the wafer remains flat and does not curl. The wafer is presses tightly and wafer breakdown is avoided.

In the embodiment, the lifting structure 30A includes a lifting component 32A and an electrical component 31A. The electrical component 31A is positioned at the free end of the lifting component 32A and connected to the lower sealing assembly in a movable manner. The electrical component 31A is configured to power the heating device and heat sink 22A for performing wafer-level burn-in testing on the wafers.

In the embodiment, the lifting structure 30A includes the lifting component 32A and electrical component 31A. After the lifting structure 30A drives the lower sealing assembly to move upward and connect to the cover plate assembly 70A, the electrical component 31A of the lifting structure 30A is used to power the heating device and the heat sink 22A in the test chamber 21A. Thus, the lifting structure 30A not only presses the wafer tightly by a lifting act, but also powers up the heating device and heat sink 22A. The structure of the wafer-level burn-in test device 100A is optimized.

In the embodiment, the lower sealing assembly also includes a sealing strip 211A disposed on the top of the lower sealing cover 20A. The sealing strip 211A is used to seal the test chamber 21A.

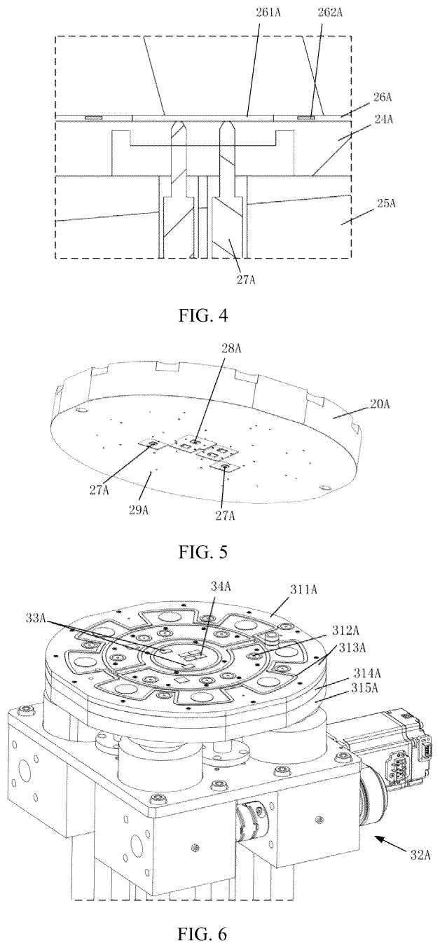

FIG. 3 is a schematic cross-sectional view of the lower sealing cover 20A in the wafer-level burn-in test device 100A shown in FIG. 1. FIG. 4 is a schematic enlarged view of a part A in FIG. 3. As shown in FIGS. 3 and 4, in the embodiment, the heating device includes a heating film layer 26A and at least one first connection probe set 27A. The heating film layer 26A has resistance wires 262A that are uniformly arranged and at least one power interface 261A connected to the resistance wires 262A. The first connection probe set 27A passes through the lower sealing cover 20A. One end of each first connection probe set 27A contacts with the power interface 261A, while the other end contacts with the electrical component 31A. Thus the electrical component 31A may power up the heating film layer 26A and heats up the wafer on the heat sink 22A. The heating film layer 26A may be a mica heating sheet or a ceramic heating sheet. The resistance wires 262A are provided between two mica film layers or ceramic film layers. The resistance wires 262A are evenly distributed in an extension plane. In the embodiment, the numbers of the first connection probe and power interface 261A are two, respectively. The first connection probe set 27A includes multiple connection probes. In some other embodiments, the number of the first connection probe and power interface 261A may also be set according to specific design requirements.

In the embodiment, the heating device also includes a second heat insulating member 25A and a first heat insulating member 24A. The test chamber 21A is provided with the second heat insulating member 25A, the first heat insulating member 24A, the heating film layer 26A, a ceramic plate 23A, and the heat sink 22A from the bottom to the top. The heating film layer 26A is disposed on the top of the first heat insulating member 24A, that is, below the ceramic plate 23A. The ceramic plate 23A has functions of heat conduction and electrical insulation. The first connection probe set 27A passes through the lower sealing cover 20A, the second heat insulating member 25A, and the first heat insulating member 24A in sequence, enabling the first connection probe set 27A to contact with the power interface 261A of the heating film layer 26A. In the embodiment, the heating device is arranged in the test chamber 21A, which is equivalent to integrating the lower sealing cover 20A with the heating device. Compared to the existing technology where an auxiliary structure is needed to make the lower sealing cover 20A contact with the heating device, the structure of the wafer-level burn-in test device 100A is simplified. The wafer heating efficiency of the heating device is improved and the wafer testing efficiency is increased.

FIG. 5 is a schematic structural diagram of the lower sealing cover 20A in the wafer-level burn-in test device 100A shown in FIG. 1. FIG. 6 is a schematic structural diagram of the lifting structure 30A in the wafer-level burn-in test device 100A shown in FIG. 1. As shown in FIGS. 5 and 6, in the embodiment, the electrical component 31A includes a second PCB 311A. The second PCB 311A is connected to an external circuit. The top of the second PCB 311A is provided with at least one first Pad position 33A. Each first Pad position 33A is arranged correspondingly to a first connection probe set 27A. As such, when the first Pad position 33A is in contact with the first connection probe set 27A, the external circuit may power the heating device through the second PCB 311A for performing heating tests on wafers. When the lifting component 32A of the lifting structure 30A drives the electrical component to move upward to abut the lower sealing cover 20A, the first Pad position 33A contacts the first connection probe set 27A, thereby achieving electrical connection. In the embodiment, the number of the first Pad position 33A is two. A second connection probe set 28A includes multiple connection probes. In some other embodiments, the number of the first Pad position 33A may be set according to actual needs.

In the embodiment, the lower sealing cover is also provided with at least one second connection probe set 28A that is in contact with the heat sink 22A. The top of the second PCB 311A is also provided with at least one second Pad position 34A. Each second Pad position 34A is arranged corresponding to a second connection probe set 28A. When the second Pad position 34A contacts the second connection probe set 28A, the external circuit may power the heat sink 22A through the second PCB 311A for performing power-on tests on a wafer. The second connection probe set 28A passes through the lower sealing cover 20A, the second heat insulating member 25A, the first heat insulating member 24A, and the ceramic plate 23A in sequence, and then contacts with the bottom of the heat sink 22A to power up the heat sink 22A for high-voltage testing on the wafer. The wafer is subjected to high-voltage testing of around 2000 volts.

In the embodiment, the lower sealing cover 20A is also provided with a third connection probe set and at least one fourth connection probe set. The top of the second PCB 311A is also provided with a third Pad position and at least one fourth Pad position. The bottom of the heat sink 22A is provided with a groove for placing a first temperature sensor. One end of the third connection probe set is in contact with the first temperature sensor, and the other end is in contact with the third Pad position to obtain the temperature of the heat sink 22A. At least one second temperature sensor is provided at the heating film layer 26A. The fourth connection probe set corresponds to the second temperature sensor and the fourth Pad position. That is, one end of the fourth connection probe set is in contact with the second temperature sensor, and the other end is in contact with the fourth Pad position. In the embodiment, the number of the second temperature sensor is two. One of the two second temperature sensors is used to obtain the temperature of the heating film layer 26A, and the other is used for overheating protection.

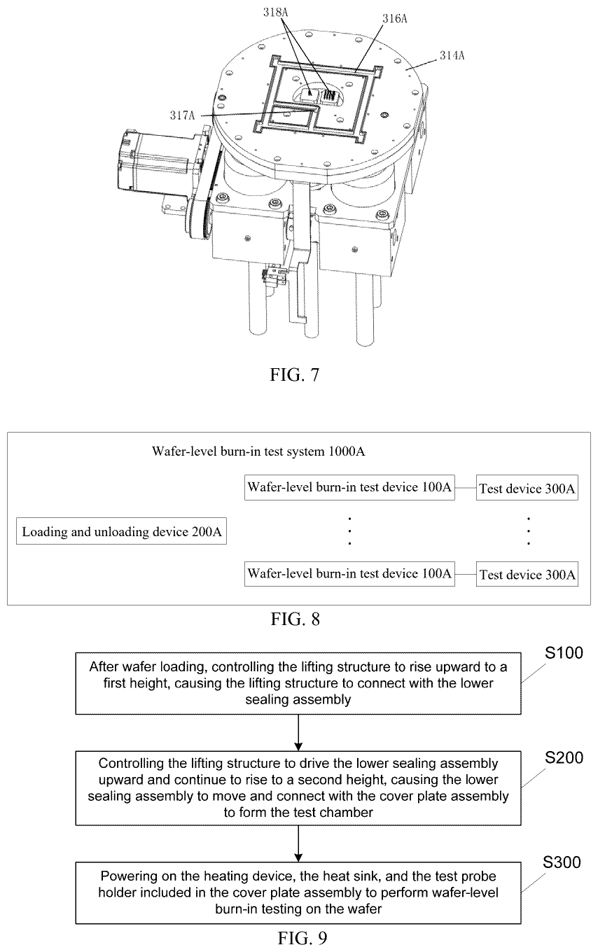

FIG. 7 is a schematic structural diagram of an adapter plate 314A in the lifting structure 30A shown in FIG. 6. As shown in FIG. 7 and referring to FIG. 6, in the embodiment, the bottom of the lower sealing cover 20A is provided with multiple first air holes 29A, and the second PCB 311A is provided with multiple second air holes 312A. Each second air hole 312A corresponds to a first air hole 29A. The electrical component 31A also includes the adapter plate 314A. The adapter plate 314A is disposed below the second PCB 311A and contains an air channel 316A connected with multiple air holes 312A. Vacuuming at the lower sealing cover 20A may be performed through an external air path and via the air channel 316A, the second air hole 312A, and the first air hole 29A. The vacuuming sucks the heat sink 22A and wafer. When the heat sink 22A is sucked, the first air hole 29A of the lower sealing cover 20A needs to be connected to the bottom of the heat sink 22A. That is, the first air hole 29A passes through the ceramic plate 23A, which is used to suck the bottom of the heat sink 22A. The first air hole 29A passes through the heat sink 22A and is used to suck the wafer. The air channel 316A has an air channel interface 317A, and the air channel interface 317A is connected to the external air channel through a connector.

In the embodiment, when wafer-level burn-in testing on wafers is performed, the test chamber 21A is filled with nitrogen gas. Nitrogen gas filling is done through the external air channel and via the air channel 316A, the second air hole 312A, and first air hole 29A. Nitrogen is used as a protective gas to prevent high-voltage sparking of the wafer during high-voltage tests.

In the embodiment, the top of the second PCB 311A is also provided with a sealing part 313A for sealing the first air hole 29A and second air hole 312A to avoid air leakage during ventilation.

In the embodiment, the adapter board 314A also includes an adapter probe set 318A. The electrical component 31A also includes a third PCB 315A disposed at the bottom of the adapter board 314A. The third PCB 315A is connected to the adapter probe set 318A and external circuits, respectively.

In the embodiment, the first PCB 11A includes a first interface set 112A and a second interface set 111A. The test probe holder 12A includes multiple test probes. The first interface set 112A is provided on a first side of the first PCB 11A facing the lower sealing assembly. One end of any test probe is connected to a corresponding first interface included in the first interface set 112A, and the other end is connected to the wafer for performing wafer-level burn-in tests. The second interface set 111A is provided on any second side of the first PCB 11A except the first side. The wafer-level burn-in test fixture 10A also includes multiple connectors 14A. The connectors 14A are mounted on the second side of the first PCB 11A. Any connector 14A is connected to a corresponding second interface included in the second interface set 111A and connected to an external test device via a wiring harness for wafer-level burn-in testing of wafers.

In the embodiment, a heat dissipation component 13A is also provided between the first interface set 112A and the second interface set 111A of the first PCB 11A. It isolates the heat generated by the first interface set 112A during wafer-level burn-in tests, and avoids affecting the normal operation of connector 14A.

In the embodiment, the connector 14A is provided at the second interface set 111A. A wire harness is used to connect the connector 14A to an external test device. The method of using probe connection in the existing technology is cancelled. Thus, rigid connection is replaced by flexible connection. Relative positions between the wafer-level burn-in test fixture 10A and the external test device may be flexibly arranged, respectively. The number of channels powering the wafer is increased. In addition, when probes are used to connect with external test devices, there are many contact points, which results in lower reliability of circuit connections. In the invention, a wire harness is used for connection, and there is no contact point. The reliability of circuit connection is thus increased.

In the embodiment, the wafer-level burn-in test device 100A also includes a mounting bracket 50A. The mounting bracket 50A includes a bottom plate assembly 51A, a support platform 55A, and a pair of first slide grooves 54A. The support platform 55A is used to support the lower sealing assembly. The pair of first slide grooves 54A is connected to the bottom plate assembly 51A. Any first slide groove 54A extends in a horizontal direction. The two ends of the support platform 55A are connected to a corresponding first groove 54A, respectively, in a sliding manner. The lower sealing assembly is driven by the support platform 55A and moves in a direction along which the first slide groove 54A extends. When wafers are loaded or unloaded, the lower sealing assembly slides along the first slide groove 54A to reach a position outside the mounting bracket 50A. When wafer loading or unloading is finished, the lower sealing assembly is retracted into the mounting bracket 50A along the first slide groove 54A.

In the embodiment, the mounting bracket 50A also includes a top plate assembly 53A and a pair of second glide grooves 40A. The top plate assembly 53A is connected to the bottom plate assembly 51A through multiple pillars 52. The pair of second glide groove 40A is connected to the top plate assembly 53A. Any second glide groove 40A extends in a horizontal direction. The two ends of the cover plate assembly 70A are connected to a corresponding second slide groove 40A, respectively, in a gliding manner. The cover plate assembly 70A may be pulled out for replacing the test probe holder 12A. In addition, the cover plate assembly 70A may be pulled out, and the wafer-level burn-in test fixture 10A may be replaced with regard to different types of wafers. It facilitates replacement of the wafer-level burn-in test fixture 10A. Wafer-level burn-in testing of wafers becomes more convenient.

In the embodiment, the wafer-level burn-in test device 100A also includes a camera device 60A. The camera device 60A is mounted on the mounting bracket 50A, and used to detect whether the lower sealing cover 20A and the cover plate assembly 70A are connected to form the test chamber 21A.

FIG. 8 is a schematic connection block diagram of a wafer-level burn-in test system 1000A according to an embodiment of the invention. As shown in FIG. 8, in the embodiment, the wafer-level burn-in test system 1000A includes a loading and unloading device 200A, at least one test device 300A, and at least one wafer-level burn-in test device 100A as illustrated above. The loading and unloading device 200A is used to place a wafer in a corresponding wafer-level burn-in test device 100A for wafer-level burn-in tests. Any wafer-level burn-in test device 100A is connected to a corresponding test device for performing wafer-level burn-in testing.

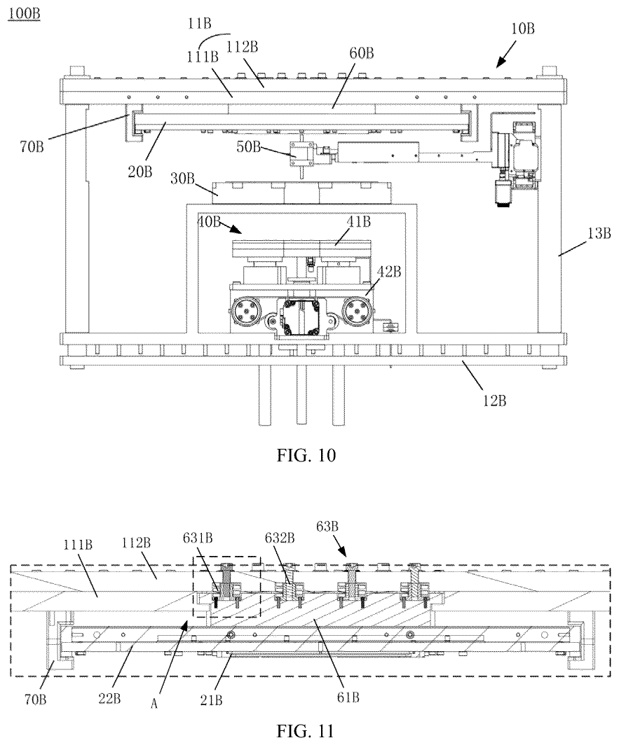

FIG. 9 is a schematic flow chart of a test method of the wafer-level burn-in test device 100A according to an embodiment of the invention. As shown in FIG. 9, the test method of the wafer-level burn-in test device 100A includes the following steps:

Step S100, after wafer loading is completed, controlling the lifting structure 30A to rise upward to a first height, causing the lifting structure 30A to connect with the lower sealing assembly;

Step S200, controlling the lifting structure 30A to continuously drive the lower sealing assembly upward and continue to rise to a second height, so that the lower sealing assembly moves and connects with the cover plate assembly 70A to form the test chamber 21A; and

Step S300, powering on the heating device, the heat sink 22A, and the test probe holder 12A included in the cover plate assembly 70A to perform wafer-level burn-in testing on wafers.

In the embodiment, the lifting structure 30A that may move up and down is used to drive the lower sealing cover 20A to rise. The lower sealing cover 20A is then driven to connect with the cover plate assembly 70A to form the test chamber 21A and press the heat sink 22A tightly. With the flat heat sink 22A, the wafer is also flat and does not curl. At the same time, the wafer is pressed tightly to avoid breakdown of the wafer.

In the embodiment, Step S300 further includes the following step:

Controlling the lifting structure 30A to move downward so that the lower sealing assembly returns to its original position.

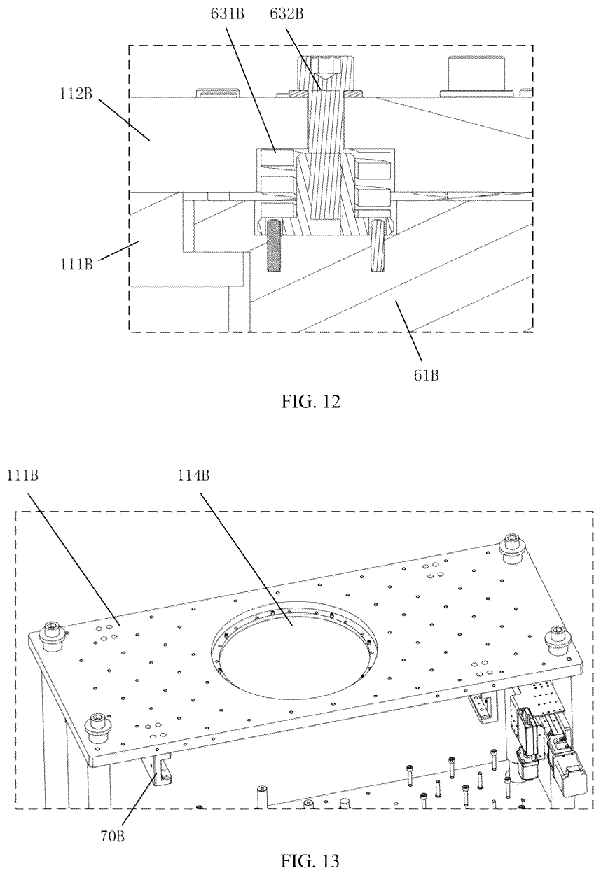

FIG. 10 is a schematic structural diagram of a wafer-level burn-in test device 100B according to an embodiment of the invention. FIG. 11 is a schematic cross-sectional view of a floating structure 60B and a top plate assembly 11B in the wafer-level burn-in test device 100B shown in FIG. 10. FIG. 12 is a schematic enlarged view of a part A in FIG. 11. FIG. 13 is a schematic structural diagram of a lower cover plate 111B in the wafer-level burn-in test device 100B shown in FIG. 10. As shown in FIGS. 10-13, in the embodiment, the wafer-level burn-in test device 100B includes a mounting bracket 10B, a wafer-level burn-in test fixture, a lifting structure 40B, and the floating structure 60B. The mounting bracket 10B includes a top plate assembly 11B and a bottom plate assembly 12B. The top plate assembly 11B and bottom plate assembly 12B are connected by a pillar 13B. The wafer-level burn-in test fixture is disposed below the top plate assembly 11B and connected to the top plate assembly 11B. The wafer-level burn-in test fixture includes a cover plate assembly 20B and lower sealing assembly. The lower sealing assembly includes a lower sealing cover 30B. The lower sealing cover 30B is connected with the cover plate assembly 20B to form a test chamber for placing a wafer. The cover plate assembly 20B has a test probe holder 21B. The lifting structure 40B is installed on the bottom plate assembly 12B and located below the lower sealing cover 30B. The lifting structure 40B is configured to extend up and down in a controlled manner. The lifting structure 40B abuts the wafer-level burn-in test fixture in a movable manner, driving the lower sealing assembly to move upward to connect with the cover plate component 20B to form the test chamber. The floating structure 60B is provided at the top plate assembly 11B. The floating structure 60B is configured to float when the cover plate assembly 20B is pressed by the lower sealing cover 30B, thereby preventing the cover plate assembly 20B from being deformed.

In the embodiment, the floating structure 60B is provided at the top plate assembly 11B of the mounting bracket 10B. The floating structure 60B is configured to float when the cover plate assembly 20B is pressed by the lower sealing cover 30B. It prevents the cover plate assembly 20B from being deformed under pressure, helps test probes on the cover plate assembly 20B contacting the wafer, and improves contact stability. The accuracy of wafer-level burn-in test is increased.

In the embodiment, the top plate assembly 11B includes an upper cover plate 112B and a lower cover plate 111B. The lower cover 111B has a limiting groove 114B. The floating structure 60B includes a floating plate 61B and an extending component 63B. The floating plate 61B is disposed on the top of the cover plate assembly 20B, located at the limiting groove 114B, and protrudes from the bottom of the lower cover plate 111B. The extending component 63B is connected to the upper cover plate 112B, and the bottom of the extending component 63B is connected to or abuts the floating plate 61B. When the floating plate 61B is pressed by the cover plate assembly 20B, it causes the floating plate 61B to move upward. It prevents the cover plate assembly 20B from being deformed under pressure and the burn-in test of wafers from being affected.

In the embodiment, the cover plate assembly 20B includes a first PCB 22B and a test probe holder 21B installed below the first PCB 22B. This embodiment is mainly to prevent the first PCB 22B from being deformed under pressure. The first PCB 22B is connected to the test probe holder 21B, and the test probe holder 21B is provided with multiple test probes. Avoiding the deformation of the first PCB 22B may prevent the occurrence of poor contact caused by movements of the test probes. In addition, the floating structure 60B may also prevent test probes from being damaged due to excessive forces. It improves the service life of test probes.

Referring to FIG. 12, the floating plate 61B is connected to the lower cover plate 111B, and there is a gap between the floating plate 61B and upper cover plate 112B. When the floating plate 61B is under greater pressure, the floating plate 61B may move in the gap. The gap is the moving stroke of the floating plate 61B. The moving stroke of the floating plate 61B may be arranged according to the design requirements.

In the embodiment, the floating plate 61B is circular and arranged opposite to the test probe holder 21B. When the lower sealing cover 30B moves upward to contact the cover plate assembly 20B, it is needed to seal the test probe holder 21B in the lower sealing cover 30B. The lower sealing cover 30B mainly contacts the surroundings of the test probe holder 21B. The force applied by the cover plate assembly 20B is mainly near or around the test probe holder 21B. In the embodiment, the floating plate 61B is arranged opposite to the test probe holder 21B. Thus, it may better prevent the first PCB 22B from being pressed and avoid deformation of the first PCB 22B.

In a preferred embodiment, the size of the floating plate 61B is larger than the size of the test probe holder 21B and smaller than the size of the lower sealing cover 30B. In some other embodiments, the size of the floating plate 61B may be set according to specific design requirements, for example, setting to be larger than the size of the lower sealing cover 30B.

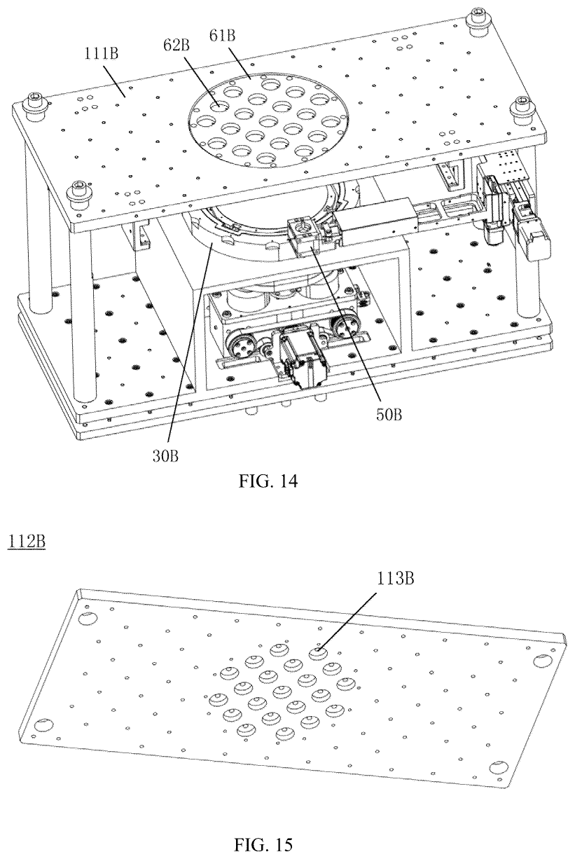

FIG. 14 is a schematic installation diagram of the floating plate 61B and the lower cover plate 111B in the wafer-level burn-in test device 100B shown in FIG. 10. FIG. 15 is a schematic structural diagram of the upper cover plate 112B of the wafer-level burn-in test device 100B shown in FIG. 10. As shown in FIGS. 14 and 15 and referring to FIG. 12, in the embodiment, the bottom of the upper cover plate 112B is provided with at least one first mounting groove 113B, and the top of the floating plate 61B is provided with at least one second mounting groove 62B. Each second mounting groove 62B corresponds to a first mounting groove 113B. The extending component 63B includes at least one elastic member 631B. Each elastic member 631B is correspondingly arranged in a first mounting groove 113B and a second mounting groove 62B. Each elastic member 631B is passed through a connecting rod 632B. The connecting rod 632B is connected to the upper cover plate 112B.

In a preferred embodiment, the number of the elastic member 631B is multiple. The elastic members 631B are evenly arranged on the top of the floating plate 61B. Both numbers of the first mounting groove 113B and second mounting groove 62B are multiple. The first mounting grooves 113B are evenly arranged at positions corresponding to the floating plate 61B. The second mounting grooves 62B are evenly arranged on the floating plate 61B. The first PCB 22B of the cover plate assembly 20B is evenly stressed, thereby avoiding local deformation of the first PCB 22B.

In the embodiment, the mounting bracket 10B also includes a pair of glide grooves 70B. The glide groove 70B is connected with the lower cover plate 111B. Any glide groove 70B extends in a horizontal direction. Two ends of the cover plate assembly 20B are slidingly connected to a corresponding slide groove 70B, respectively. The cover plate assembly 20B may be taken out from the top plate assembly 11B. Corresponding cover plate assembly 20B may be replaced for different types of wafers. It facilitates replacement of cover plate assembly 20B, improving the convenience of wafer-level burn-in tests. In addition, it may also facilitate the replacement of the test probe holder on the cover plate assembly 20B.

In the embodiment, the wafer-level burn-in test device 100B also includes a camera device 50B. The camera device 50B is installed on the mounting bracket 10B. The camera device 50B is used to detect whether the first PCB 22B is connected to form a test chamber when the lower sealing cover 30B abuts the cover plate assembly 20B.

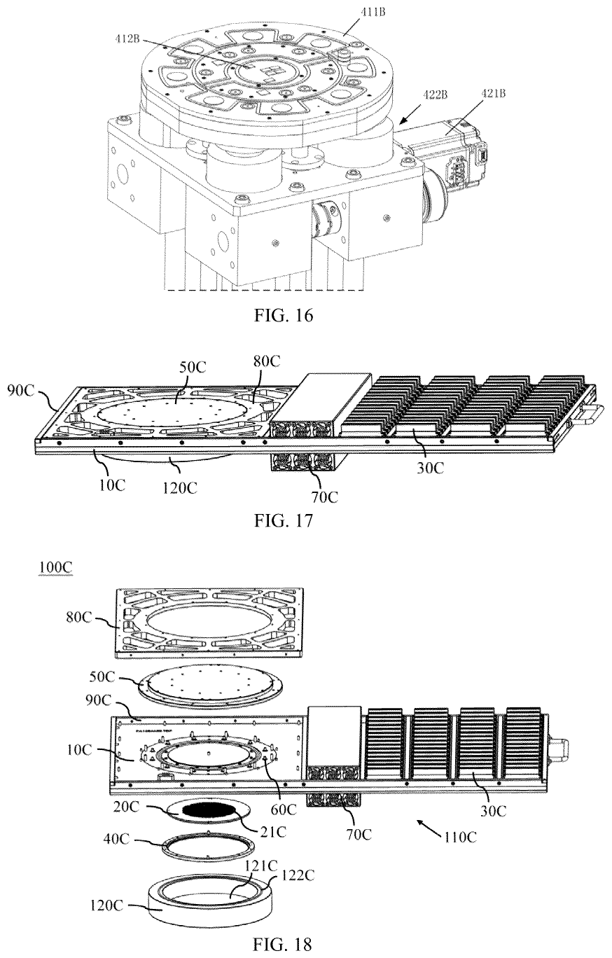

FIG. 16 is a schematic structural diagram of the power supply and ventilation device in the wafer-level burn-in test device shown in FIG. 10. As shown in FIG. 16 and referring to FIG. 10, in the embodiment, the wafer-level burn-in test fixture also includes a heat sink and a heating device. The heat sink and heating device are arranged in the test chamber. The lifting structure 40B includes an electrical component 41B. The electrical component 41B includes a second PCB 411B. The top of the second PCB 411B has a Pad position 412B for powering the heat sink and heating device to perform wafer-level burn-in tests of wafers.

In the embodiment, the lifting structure 40B also includes a lifting component 42B connected to the electrical component 41B. The electrical component 41B is located at the free end of the lifting component 42B. The lifting component 42B is used to drive the electrical component 41B to move upward, cause the Pad position 412B to cooperate with the lower sealing cover 30B, and drive the lower sealing cover 30B to move upward until the lower sealing cover 30B abuts and connect to the cover plate assembly 20B to form a test chamber.

During the lifting process of the lifting structure 40B, the Pad position on the top of the second PCB 411B of the electrical component 41B is used to cooperate with the lower sealing cover 30B, powering up the heating device and heat sink to enable high-voltage high-temperature testing of wafers. The lifting structure 40B not only rises to press a wafer, but also provides test conditions for the wafer at the lower sealing cover 30B. The structure of the wafer-level burn-in test device 100B is optimized.

In the embodiment, the lifting component 42B includes multiple turbine shafts 422B and a motor 421B. The turbine shafts 422B are connected to the electrical component 41B, respectively. The motor 421B is connected to the turbine shafts 422B, driving the turbine shafts 422B to raise or lower the electrical component 41B. In some other embodiments, the lifting structure 42B may use other components, such as cylinders, etc.

The present invention also provides a wafer-level burn-in test fixture. The wafer-level burn-in test fixture includes a cover plate assembly and a lower sealing assembly. The cover plate assembly and lower sealing assembly are connected to form a test chamber for accommodating wafers.

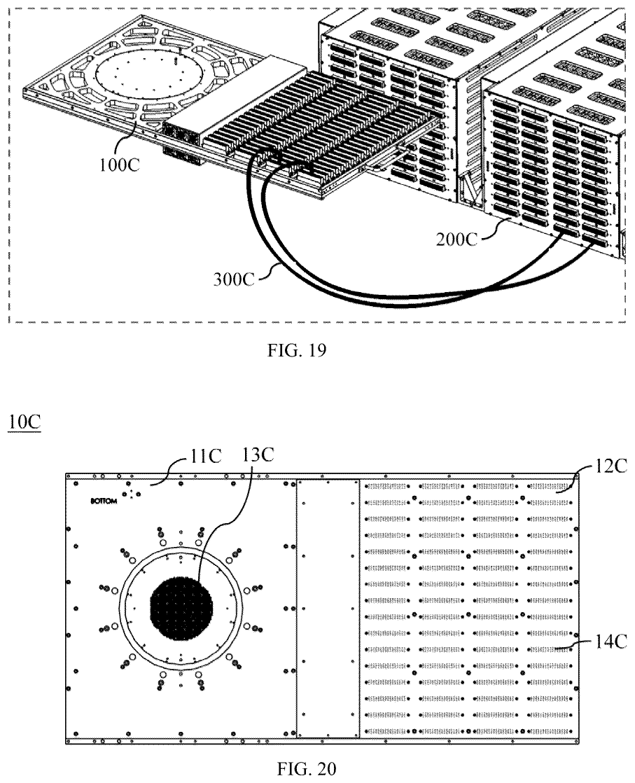

FIG. 17 is a schematic structural diagram of a wafer-level burn-in test fixture 100C according to an embodiment of the invention. FIG. 18 is a schematic exploded view of the wafer-level burn-in test fixture 100C according to an embodiment of the invention. FIG. 19 is a schematic position diagram of the wafer-level burn-in test fixture 100C and an external test device 200C according to an embodiment of the invention. FIG. 20 is a schematic structural diagram of a PCB 10C shown in FIG. 18. As shown in FIGS. 17-20, in some embodiments, the wafer-level burn-in test fixture 100C includes a cover plate assembly 110C and a lower sealing assembly 120C. The cover plate assembly 110C and lower sealing assembly 120C are connected to form a test chamber 121C for receiving wafers. The cover plate assembly 110C includes the PCB 10C, a test probe holder 20C, and at least one connector 30C. The PCB 10C includes a first area 11C and a second area 12C. The first area 11C and second area 12C are respectively located on different sides of the PCB 10C. Any first contact point 13C provided in the first area 11C is electrically connected to a corresponding second contact point 14C provided in the second area 12C. The test probe holder 20C is located at the bottom of the PCB 10C and connected to the PCB 10C. The test probe holder 20C contains multiple test probes 21C. One end of any test probe 21C is in contact with a corresponding first contact point 13C, and the other end is in contact with the wafer for performing wafer-level burn-in tests on wafers. The connector 30C is installed in the second area 12C of the PCB 10C. Any connector 30C is connected to a corresponding second contact point 14C and the external test device 200C through a wire harness 300C, respectively, for performing wafer-level burn-in testing on wafers.

In the embodiment, the test probe holder 20C is provided with pinholes. The test probe 21C is a spring probe and mounted in the pin hole. The test probe 21C touches a chip of the wafer to power up the chip. The first area 11C and second area 12C are two areas on the PCB 10C that do not overlap and have electrical connections. The surface of the first area 11C is provided with the first contact point 13C. Any first contact point is electrically connected to a corresponding second contact point 14C provided in the second area 12C through an internal circuit on the PCB 10C. The external test device 200C is connected to the connector 30C in the second area 12C through the flexible wire harness 300C or a cable. The second area 12C passes test signals to the first area 11C. The first area 11C transmits the signals to the wafer in the test chamber 121C through the test probe 21C. As such, wafer-level burn-in testing on the wafer may be conducted. The connector 30C and external test device 200C are connected by flexible connection. It has a simple structure and flexible and reliable layout.

In the embodiment, the connector 30C is provided in the second area 12C of the PCB 10C. The wire harness 300C is used to connect the connector 30C to the external test device 200C. The method of probe connection used in the prior art is canceled. It is equivalent to rigid connections being replaced by flexible connections. Thus, relative positions between the wafer-level burn-in test fixture 100C and external test device 200C may be flexibly arranged, respectively. The structural correlation between the wafer-level burn-in test fixture 100C and external test device 200C is reduced. The number of channels powering the wafer may be increased. In addition, when a probe is used to connect to the external test device 200C, there are many contact points, which may result in lower reliability of circuit connection. When the wiring harness 300C is used for connection, there is no contact point. The reliability of circuit connection is improved. Further, the wafer-level burn-in test fixture 100C may be installed and removed independently and conveniently. The maintainability is also improved.

In the invention, the wafer-level burn-in test fixture 100C has a compact structure and high integration, provides a higher number of channels to connect to hardware with a smaller size, supports up to 8-inch SiC wafers for wafer-level burn-in testing, and provides over 2,000 channels for power-up and wafer-level burn-in testing.

In the embodiment, there are multiple connectors 30C. The connectors 30C are arranged in an array on the PCB 10C. The connectors 30C are densely mounted in the second area 12C and connected to the external test device 200C through the flexible wire harness 300C or a cable. The array arrangement of the connectors 30C may make full use of the second area 12C of the PCB 10C and save the usage area of the PCB 10C. It may further increase the number of powered channels per unit area to achieve high-density multi-channel wafer-level burn-in testing.

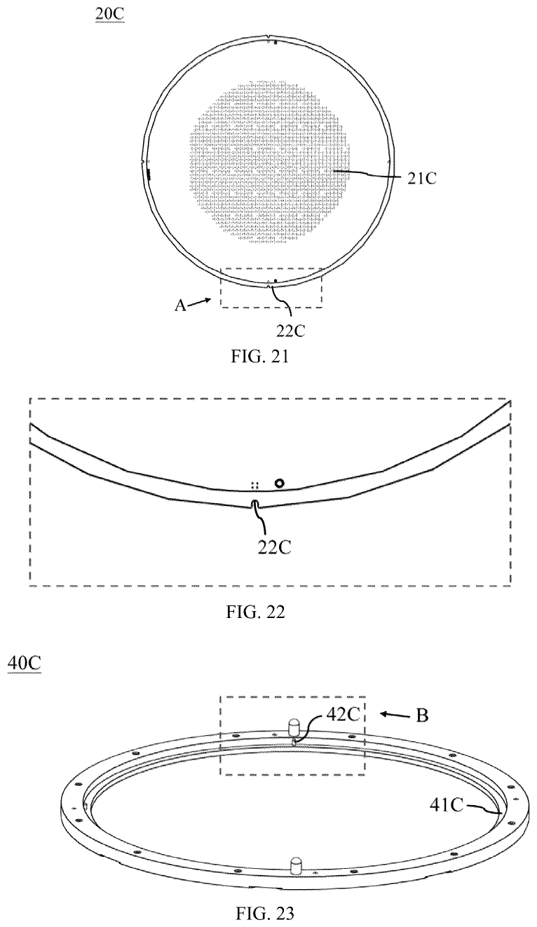

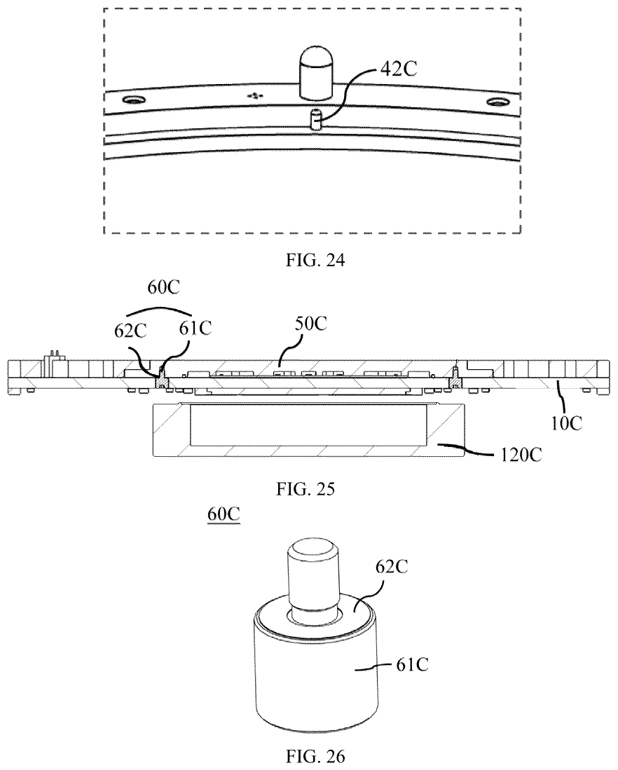

FIG. 21 is a schematic structural diagram of the test probe holder 20C according to an embodiment of the invention. FIG. 22 is a schematic enlarged view of a part A in FIG. 21. FIG. 23 is a schematic structural diagram of the connector 40 according to an embodiment of the invention. FIG. 24 is a schematic enlarged view of a part B in FIG. 23. As shown in FIGS. 21-24, in the embodiment, the test probe holder 20C is round and the wafer-level burn-in test fixture 100C further includes a ring-shaped connector 40C. The connector 40C is connected to the PCB 10C, sleeving on the outer periphery of the test probe holder 20C, and connected to the test probe holder 20C. The connector 40C presses the test probe holder 20C and is snap-connected with the test probe holder 20C. It makes the test probe holder 20C and the PCB 10C relatively fixed. The structural stability of the wafer-level burn-in test fixture 100C is increased. In the embodiment, the connector 40C is connected to the PCB through bolts.

In the embodiment, the test probe holder 20C is made of materials with high hardness and low expansion coefficient. During the use of the wafer-level burn-in test fixture 100C, the test probe holder 20C and PCB 10C are fixed at specific positions and there is no relative displacement. Otherwise, the test probe 21C at the test probe holder 20C may not contact the PCB 10C and open circuit may occur. In the existing technology, a test probe holder 20C and a connector 40C are positioned through the cooperation of pins and cylindrical holes. Because the maximum ambient temperature of the test probe holder is close to 200° C. when in use, the high temperature may cause the test probe holder and connector to expand. The two materials are different and have a large difference in expansion coefficient, which may cause the pin and the cylindrical hole to press each other and generate great stress. This then may lead to problems such as the test probe holder being cracked and damaged or the connector being deformed and becoming difficult to disassemble.

In the embodiment, the edge of the test probe holder 20C is provided with at least one groove 22C. The connector 40C has a support portion 41C for supporting the test probe holder 20C. The support portion 41C is provided with at least one positioning post 42C. Each positioning post 42C is arranged corresponding to a groove 22C to position the test probe holder 20C. The cooperation of the positioning post 42C and groove 22C defines the position of the test probe holder 20C. When the test probe holder 20C and the connector 40C expand due to heat, the positioning post 42C may slide a small amount in the groove 22C without pressing the groove 22C. It eliminates the stress when the test probe holder 20C and connector 40C expand, and avoids deformation of the test probe holder 20C and connector 40C. In the embodiment, the numbers of both groove 22C and positioning post 42C are set to three, and the three grooves 22C are distributed at the edge of the probe holder with circumferential intervals.

In the embodiment, the opening of the groove 22C is arranged toward a corresponding positioning post 42C. The groove 22C is not closed. The positioning post 42C only contacts the two sides of the groove 22C along the circumferential direction of the probe holder. When the test probe holder 20C and connector 40C expand due to heat, the positioning post 42C may slide a small distance in the groove 22C along the radial direction of the test probe holder 20C. The positioning post 42C does not press the groove 22C, which avoids deformation due to stress generated when the test probe holder 20C and connector 40C expand.

The cover plate assembly 110C is connected with the lower sealing assembly 120C to form an airtight sealed test chamber 121C. The top of the lower sealing assembly 120C is provided with a sealing ring 122C. When the lower sealing assembly 120C moves upward, the sealing ring 122C is first connected to the PCB 10C and then is pressed. After the sealing ring 122C is pressed, an airtight seal is formed. The airtight test chamber 121C has a certain air pressure, which generates a pressing force to combine the lower sealing assembly 120C and PCB 10C. But if the pressing force in the test chamber 121C is too large, the lower sealing assembly 120C may contact the PCB 10C and transmit the excessive force to the PCB 10C.

FIG. 25 is a schematic position diagram of a load-bearing component 60C according to an embodiment of the invention. FIG. 26 is a schematic structural diagram of the load-bearing component 60C shown in FIG. 25. As shown in FIGS. 25 and 26, in the embodiment, the wafer-level burn-in test fixture 100C also includes a circular upper sealing cover 50C. The upper sealing cover 50C is disposed on top of PCB 10C. The wafer-level burn-in test fixture 100C also includes multiple load-bearing components 60C spaced apart along the circumferential direction of the upper sealing cover 50C. Each load-bearing component 60C includes a load-bearing column 61C. The load-bearing column 61C passes through the PCB 10C, connects to the upper sealing cover 50C, and protrudes from the bottom surface of PCB 10C. The upper sealing cover 50C is tightly connected to the PCB 10C through the sealing ring 122C of the lower sealing assembly 120C, which provides air tightness for the top of the first area 11C. The PCB 10C is provided with load-bearing columns 61C spaced apart along the circumferential direction of the upper sealing cover 50C. The load-bearing column 61C protrudes from the bottom surface of the PCB 10C. When the pressing force in the test chamber 121C is too large and the lower sealing cover 120C is too close to the PCB 10C, the load-bearing column 61C contacts the lower sealing cover 120C before the PCB 10C and withstands the pressing force of the test chamber 121C. It prevents the PCB 10C from being subjected to excessive pressure.

In the embodiment, the height of the load-bearing column 61C protruding from the bottom surface of the PCB 10C is, e.g., any value in the range of 0.1 mm˜0.2 mm. If the height of the load-bearing column 61C protruding from the bottom surface of the PCB 10C is too high, it may affect the sealing between the PCB 10C and the lower sealing cover 120C. If the height is too low, it may not be easy to perform the load-bearing function. In the embodiment, the height of the load-bearing column 61C protruding from the bottom surface of the PCB 10C is 0.1 mm. When the pressing force of the test chamber 121C is too large, the load-bearing column 61C may be connected to the lower sealing cover 120C before the PCB 10C, thereby preventing the PCB 10C from being damaged by excessive pressure.

In the embodiment, the load-bearing component 60C also includes at least one sleeve 62C sleeving on the load-bearing column 61C to adjust the height of the load-bearing column 61C protruding from the bottom surface of the PCB 10C. In the embodiment, the thickness of each sleeve 62C is 0.1 mm. The height of the load-bearing column 61C protruding from the bottom surface of the PCB 10C may be adjusted by adjusting the number of the sleeve 62C.

In the embodiment, the wafer-level burn-in test fixture 100C also includes a heat dissipation component 70C mounted on the PCB 10C. The heat dissipation component 70C is located between the first area 11C and second area 12C and used to isolate the heat generated at the first area 11C. During wafer-level burn-in tests, a wafer may be continuously heated, and the temperature at the first area 11C is relatively high. The heat may spread to other areas of the PCB 10C. The high temperature has a negative impact on the connector 30C, which in turn affects the accuracy of the wafer-level burn-in test. In order to avoid high temperature affecting the connector 30C, the heat dissipation component 70C is provided between the first area 11C and second area 12C.

In the embodiment, a copper sheet is laid on the surface of a location where the heat dissipation component 70C is installed on the PCB 10C. It makes the heat diffused in the first area 11C to concentrate at the position where the heat dissipation component 70C is installed. The heat dissipation component 70C includes a fan and a heat sink plate. The fan is located at the edge of the PCB 10C along the width direction to generate airflow that takes away heat. The airflow blows from one side of the PCB 10C to the other side in the width direction to prevent the heat in the first area 11C from spreading to the second area 12C. It avoids high temperature affecting the connector 30C, protects the wafer-level burn-in test fixture 100C, and improves the accuracy of wafer-level burn-in tests.

In the embodiment, the wafer-level burn-in test fixture 100C also includes a structural member 80C located on the top of the PCB 10C and connected to the upper sealing cover 50C. The wafer-level burn-in test fixture 100C further includes multiple reinforcement members 90C located on the top of the PCB 10C. The reinforcement members 90C are respectively provided on the peripheral side of the structural member 80C, the edge of the PCB 10C, and the second area 12C. By screws, the reinforcement members 90C are fastened around the PCB 10C and between adjacent connectors 30C in the second area 12C. It enhances the structural strength of the wafer-level burn-in test fixture 100C. As the structural member 80C is connected to the reinforcement member 90C in the first area 11C and the PCB 10C at the same time, it provides the strength to stressed parts of the PCB 10C.

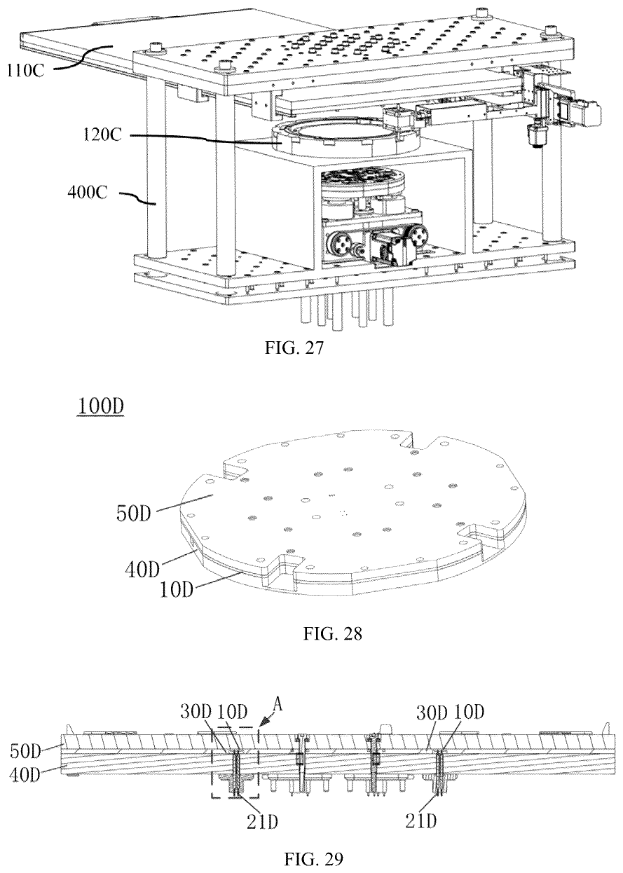

FIG. 27 is a schematic structural diagram of a lifting structure 400C according to an embodiment of the invention. As shown in FIG. 27, a wafer-level burn-in test device is provided that includes the wafer-level burn-in test fixture 100C and lifting structure 400C. The lifting structure 400C is configured to extend up and down in a controlled manner, abuts the wafer-level burn-in test fixture 100C in a movable manner, and drives the lower sealing assembly 120C to move upward to connect with the cover plate assembly 110C to form the test chamber 121C.

Before the wafer-level burn-in test fixture 100C is used, the connector 30C is first connected to the external test device 200C and a hardware loop. When the wafer-level burn-in test fixture 100C is in operation, the cover plate assembly 110C is connected with the lower sealing assembly 120C to form the airtight test chamber 121C, so that wafer-level burn-in testing on wafers may be performed. Specifically, a wafer is placed at a specific position in the test chamber 121C and the cover plate assembly 110C does not move. The lower sealing assembly 120C is lifted upward along a direction from the bottom of the test probe holder 20C. The lower sealing assembly 120C is lifted until the lower sealing assembly 120C connects with the PCB 10C and is compressed slightly. The airtight sealed test chamber 121C is formed.

During the lifting process of the lower sealing assembly 120C, the test probes 21C on the test probe holder 20C may touch test points at specific positions on the wafer surface. The test probes 21C are spring probes, which may shorten a certain stroke. The tip of the test probe 21C contacts the surface of the wafer and generates a certain amount of pressure, forming a circuit for powered burn-in and testing of the wafer. At this time, the wafer may be powered on and burn-in and tests may be performed. The lower sealing assembly 120C along with the PCB 10C and the upper sealing cover 50C together form an airtight space. Specific compressed gas may be filled into the airtight space to protect the wafer. During high-voltage testing, the compressed gas may prevent high-voltage arcing from damaging the test probe 21C or the wafer.

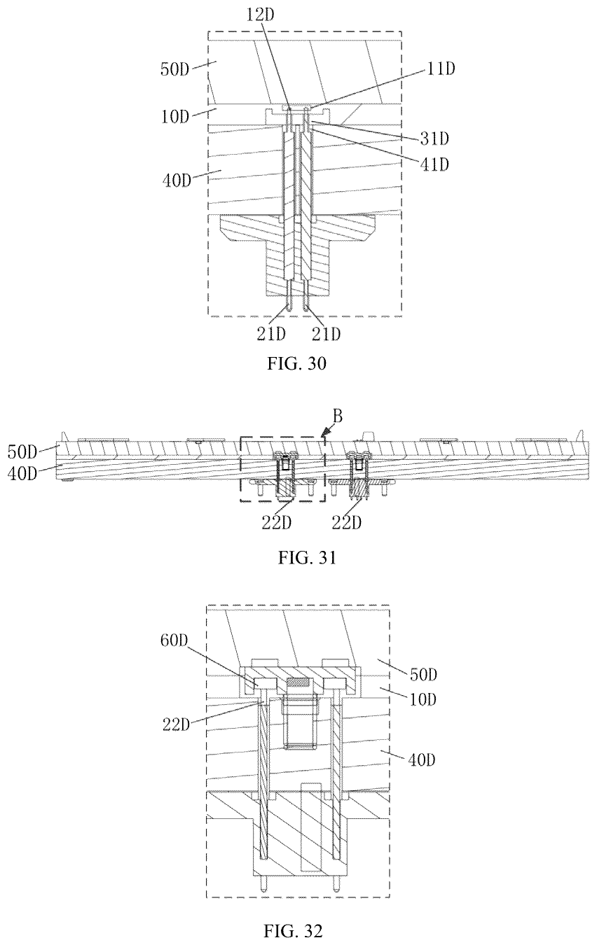

FIG. 28 is a schematic structural diagram of a heating device according to an embodiment of the invention. FIG. 29 is a schematic cross-sectional view of a heating device according to an embodiment of the invention. FIG. 30 is a schematic partial enlarged view of a part A shown in FIG. 29. FIG. 31 is a schematic cross-sectional view from another angle of the heating device according to an embodiment of the invention. FIG. 32 is a schematic partial enlarged view of a part B shown in FIG. 31. As shown in FIGS. 28-32, in some embodiments, a wafer-level burn-in test fixture 400D is provided. The wafer-level burn-in test fixture 400D includes a cover plate assembly 80D, a lower sealing assembly 210D, and a heat sink 230D for carrying a wafer 300D. The cover plate assembly 80D is connected with the lower sealing assembly 210D to form a test chamber 211D. The heat sink 230D and a heating device 100D are disposed in the test cavity 211D, respectively. The heat sink 230D is stacked on the top of the heating device 100D. The heating device 100D is electrically connected to an electrical component 226D located below the lower sealing assembly 210D. The heating device 100D includes a heating film layer 10D, and has evenly arranged resistance wires 11D and at least one power interface 12D connected to the resistance wires 11D. The heating film layer 10D is disposed on a side of the heat sink 230D away from the wafer 300D to heat the wafer 300D through the heat sink 230D. A connection assembly 20D includes at least one first connection probe set 21D that passes through the lower sealing assembly 210D. One end of any first connection probe set 21D is in contact with a corresponding power interface 12D, and the other end passes through the lower sealing assembly 210D and contacts the electrical component 226D. As such, the electrical component 226D supplies power to and heats the heating film layer 10D, thereby heating the wafer 300D on the heat sink 230D.

The heating film layer 10D is in contact with the lifting structure 220D through the first connection probe set 21D, so that the lifting structure 220D may supply power to the resistance wires 11D inside the heating film layer 10D. The heating film layer 10D is powered on and uniformly heated through the power interface 12D, which enables the heating device 100D to uniformly heat up the wafer 300D, preventing the wafer 300D from being damaged or test results being affected due to uneven heating. The test chamber 211D of the lower sealing assembly 210D is provided sequentially with the wafer 300D, heat sink 230D, and heating device 100D from top to bottom. The number of the first connection probe set 21D may be one or more, and the number of the power interface 12D may be one or more.

As shown in FIG. 30, in the embodiment, evenly arranged resistance wires 11D are provided in the heating film layer 10D. The first connection probe set 21D is in conductive contact with the power interface 12D of the heating film layer 10D and the lifting structure 220D, respectively. The resistance wires 11D are electrically connected and heated, so that the heating film layer 10D may uniformly heat the wafer 300D on the heat sink 230D. It avoids damage to the wafer 300D due to uneven heating and increases the yield rate of the wafer 300D. The heating film layer 10D is electrically connected and heated through the connection between the first connection probe set 21D and the lifting structure 220D. The path of heat transfer goes through the heating film layer 10D, heat sink 230D, and wafer 300D. It may prevent the wafer 300D from being damaged due to direct contact with the heating device 100D, and reduce the defective rate of the wafer 300D.

In the embodiment, the heating film layer 10D of the heating device 100D has uniformly arranged resistance wires 11D and at least one power interface 12D connected to the resistance wires 11D. The first connection probe set 21D is directly connected to the resistance wires 11D through the power interface 12D to achieve uniform heating of the heating film layer 10D. It avoids the need for setting multiple probe assemblies corresponding to multiple heating sheets, and simplifies the structure of the heating device 100D.

In the embodiment, the heating film layer 10D is a mica heating sheet or a ceramic heating sheet. Specifically, the resistance wires 11D are evenly distributed inside the mica heating sheet or ceramic heating sheet, and the lifting structure 220D is connected to the resistance wires 11D through the first connection probe set 21D. The mica heating sheet or ceramic heating sheet is powered on to be heated. The heating device 100D uniformly heats up the wafer 300D disposed above the heat sink. The size of the mica heating sheet or ceramic heating sheet is the same as the size of the heat sink 230D, so that the heating device 100D may evenly heat the heat sink 230D, and the wafer 300D may be evenly heated.

In a preferred embodiment, the heating film layer 10D is a mica heating sheet. The preparation cost of the mica heating sheet is low, and thus the manufacturing cost of the heating device 100D may be reduced.

In the embodiment, the heating device 100D also include first thermal insulation element 30D. The first thermal insulation element 30D is positioned below the heat sink 230D. The heating film layer 10D and first thermal insulation element 30D are integrated. Specifically, the first thermal insulation element 30D is integrated with the heating film layer 10D and is located at the bottom of the heating film layer 10D. It avoids direct contact between the heating film layer 10D and lower sealing assembly 210D when the heating film layer 10D is heated to a high temperature, thereby avoiding damages to the wafer-level burn-in test device 200D.

In the embodiment, the heating film layer 10D is located on a side of the first thermal insulation element 30D close to the heat sink 230D. The first thermal insulation element 30D is provided with a first through hole 31D at a position corresponding to the power interface 12D, so that any first connection probe set 21D may pass through the first through hole 31D to contact the power interface 12D. Optionally, the heating film layer 10D is integrated with the first thermal insulation element 30D. The first connection probe set 21D is in contact with the power interface 12D of the heating film layer 10D through the first through hole 31D of the first thermal insulation element 30D. The lifting structure 220D is in conductive contact with the resistance wires 11D in the heating film layer 10D, so that the heating film layer 10D is powered on and heated. Thus, the heating film layer 10D may uniformly heat the wafer 300D. The number of the first through hole 31D is two, and the number of the first connection probe set 21D is two. Each first through hole 31D corresponds to a first connection probe set 21D, and the two first through holes 31D are symmetrically arranged about the center line of the first thermal insulation element 30D.

In the embodiment, also included is a second thermal insulation element 40D. The second thermal insulation element 40D is located on a side of the first thermal insulation element 30D away from the heat sink 230D, and has a second through hole 41D corresponding to the first through hole 31D. Any first connection probe set 21D passes through the first through hole 31D and second through hole 41D to contact the power interface 12D. Specifically, the second thermal insulation element 40D is provided below the first thermal insulation element 30D to isolate the heat of the heating film layer 10D. The number of the second through hole 41D is two. One end of each first connection probe set 21D passes through the first through hole 31D to contact the power interface 12D of the heating film layer 10D, and the other end passes through the second through hole 41D to contact the power interface 12D of the heating film layer 10D. As such, the heating device 100D is connected to the lifting structure 220D through the first connection probe set 21D, enabling powering and heating the heating film layer 10D. Then, the wafer 300D may be heated up.

In the embodiment, the heating device 100D also includes a ceramic plate 50D. The ceramic plate 50D is located between the heating film layer 10D and the heat sink 230D, and is used to transfer the heat generated by the heating film layer 10D to the heat sink 230D. Specifically, the ceramic plate 50D is arranged between the heating film layer 10D and heat sink 230D, and the size of the ceramic plate 50D is the same as the size of the heating film layer 10D and the heat sink 230D. Thus, the ceramic plate 50D may evenly transfer the heat of the heating film layer 10D to the heat sink 230D, and then transfer the heat to the wafer 300D. It avoids overheating the heat sink 230D due to direct contact between the heating film layer 10D and the heat sink 230D, and prevents the wafer 300D from being overheated and damaged.

As shown in FIG. 32, in the embodiment, the heating device 100D also includes at least one first temperature sensor 60D and at least one second connection probe set 22D. The first temperature sensor 60D is disposed at the heating film layer 10D for detecting the temperature of the heating film layer 10D. Any second connection probe set 22D corresponds to a first temperature sensor 60D and passes through the lower sealing assembly 210D. One end of the second connection probe set 22D is in contact with the first temperature sensor 60D, and the other end is in contact with the lifting structure 220D. Optionally, the second connection probe set 22D is used to connect the first temperature sensor 60D located at the heating film layer 10D to the lifting structure 220D. It enables the first temperature sensor 60D to detect the temperature of the heating film layer 10D in real time, avoids irreversible damage to the heat sink 230D and the wafer 300D when the temperature of the heating film layer 10D is too high, and at the same time, prevents the lifting structure 220D located below the lower sealing assembly 210D from being damaged by overheating. Exemplarily, the number of the first temperature sensor 60D may be two, and the number of the second connection probe set 22D may be two. Each first temperature sensor 60D corresponds to a second connection probe set 22D. The two second connection probe sets 22D are respectively a main temperature control test probe set and an overheating protection probe set of the heating film layer 10D.

In the embodiment, the heating device 100D also includes a second temperature sensor 70D and a third connection probe set 23D. The second temperature sensor 70D is arranged at the heat sink 230D and used to detect the temperature of the heat sink 230D. Each third connection probe set 23D corresponds to a second temperature sensor 70D, and passes through the lower sealing assembly 210D, the second thermal insulation element 40D, the first thermal insulation element 30D, the heating film layer 10D, and the ceramic plate 50D in sequence. One end of the third connection probe set 23D is in contact with the second temperature sensor 70D, and the other end is in contact with the lifting structure 220D. It allows the second temperature sensor 70D to detect the temperature of the heat sink 230D when the power is on, prevents the heat sink 230D from being overheated and damaging the wafer 300D, and improves the yield rate of the wafer 300D.

In the embodiment, the heating device 100D also includes a fourth connection probe set 24D that is in direct contact with the heat sink 230D. Each fourth connection probe set 24D passes through the lower sealing assembly 210D, the second thermal insulation element 40D, the first thermal insulation element 30D, the heating film layer 10D, and the ceramic plate 50D in sequence until it abuts the heat sink 230D. One end of the fourth connection probe set 24D is in contact with the heat sink 230D, and the other end is in contact with the lifting structure 220D. As such, the lifting structure 220D may power the heat sink 230D. Then the wafer 300D may be tested when the power is on.

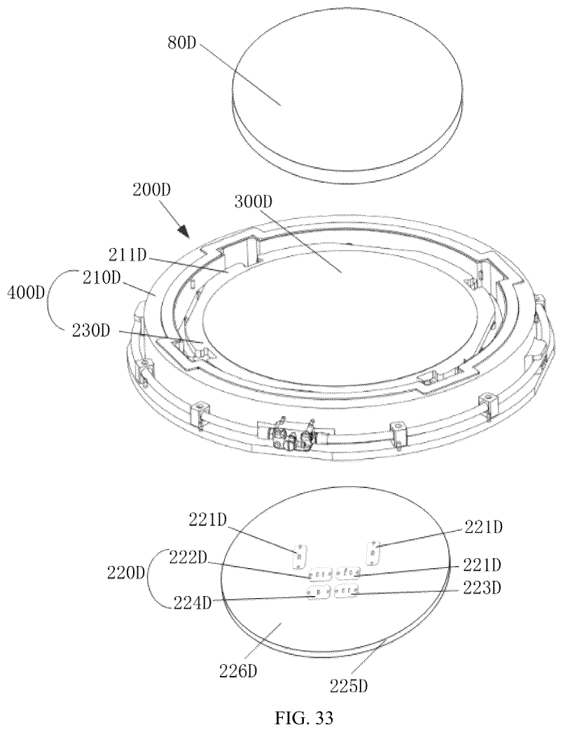

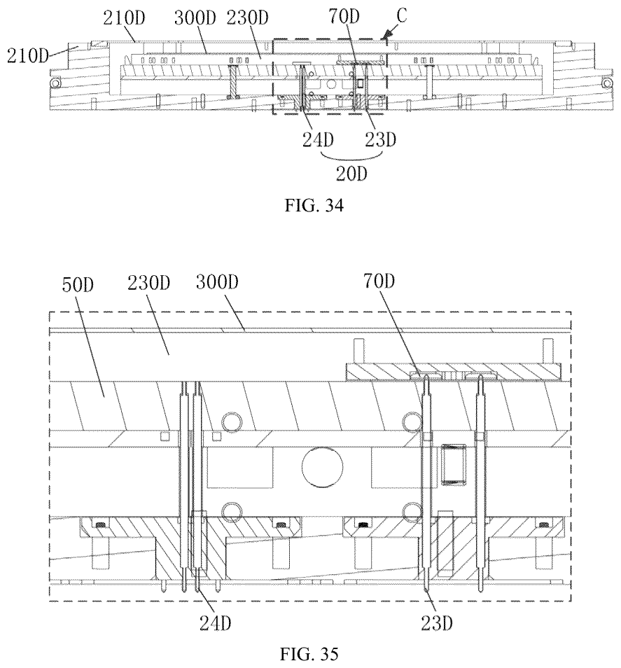

FIG. 33 is a schematic structural diagram of the wafer-level burn-in test device 200D according to an embodiment of the invention. FIG. 34 is a schematic cross-sectional view of a partial structure of the wafer-level burn-in test device 200D according to an embodiment of the invention. FIG. 35 is a schematic partial enlarged view of a part C shown in FIG. 34. As shown in FIGS. 33-35, the wafer-level burn-in test device 200D includes a wafer-level burn-in test fixture 400D and a lifting structure 220D. The lifting structure 220D includes a lifting component 225D and electrical component 226D. The electrical component 226D is located at the free end of the lifting component 225D. The electrical component 226D is configured to power the heating device 100D when being connected to the wafer-level burn-in test fixture 400D. Then, the wafer 300D may be heated for performing wafer-level burn-in tests.

Specifically, the wafer-level burn-in test device 200D includes the lower sealing assembly 210D, wafer 300D, heat sink 230D, and heating device 100D, which are sequentially arranged from top to bottom in the test chamber 211D of the lower sealing assembly 210D. The lifting structure 220D is provided below the lower sealing assembly 210D to power the heating film layer 10D. The two ends of the first connection probe set 21D in the heating device 100D are respectively connected to the lifting structure 220D and the heating film layer 10D to power and heat the heating film layer 10D. Then, the heat sink 230D and wafer 300D located above heat sink 230D are heated. The wafer-level burn-in test device 200D may be used to perform high-temperature wafer-level burn-in tests on the wafer 300D.

In the embodiment, a surface of the lifting structure 220D facing the wafer-level burn-in test fixture is provided with at least one first Pad position 221D. Each first connection probe set 21D of the heating device 100D passes through the lower sealing assembly 210D to contact the first Pad position 221D, so that the electrical component 226D may supply power to the heating film layer 10D. Specifically, the first connection probe set 21D passes through the lower sealing assembly 210D to contact the first Pad position on the top of the lifting structure 220D, so that the lifting structure 220D may power and heat the heating film layer 10D. The number of the first Pad position 221D is two. Each first Pad position 221D is arranged corresponding to a power interface 12D of the heating film layer 10D.

In the embodiment, the top of the lifting structure 220D is provided with at least one second Pad position 222D. One end of each second connection probe set 22D of the heating device 100D passes through the lower sealing assembly 210D to contact a second Pad position 222D, and the other end is in contact with the first temperature sensor 60D in the heating film layer 10D. As such, the lifting structure 220D may supply power to the first temperature sensor 60D and detect the temperature of the heating film layer 10D in real time. It avoids overheating of the heating film layer 10D and damaging other structures of the wafer-level burn-in test device 200D. The number of the second Pad position 222D is two. Each second Pad position 222D is arranged corresponding to a first temperature sensor 60D of the heating film layer 10D.

In the embodiment, the top of the lifting structure 220D is provided with a third Pad position 223D. One end of the third connection probe set 23D of the heating device 100D passes through the lower sealing assembly 210D to contact a third Pad position 223D, and the other end is in contact with the second temperature sensor 70D in the heat sink 230D. So the lifting structure 220D may supply power to the second temperature sensor 70D and detect the temperature of the heat sink 230D in real time. It may avoid excessive temperature of the heat sink 230D and damages to the wafer 300D.

In the embodiment, the top of the lifting structure 220D is provided with a fourth Pad position 224D. One end of the fourth connection probe set 24D of the heating device 100D passes through the lower sealing assembly 210D to contact the fourth Pad position 224D, and the other end is in contact with the heat sink 230D, so that the lifting structure 220D may power the heat sink 230D. Then, the wafer 300D may be powered on for testing.

In the embodiment, the number of the first Pad position 221D is the same as the number of the first connection probe set 21D. The first Pad positions 221D correspond to the first connection probe sets 21D respectively in a one-to-one manner. Specifically, each first Pad position 221D corresponds to a first connection probe set 21D. Thus, each power interface 12D of the heating film layer 10D is arranged correspondingly to a first connection probe set 21D. This enables two power interfaces 12D of the heating film layer 10D to supply power for heating at the same time. The heating efficiency of the heating film layer 10D is increased.

In the embodiment, the heating device 100D includes the heating film layer 10D and connecting assembly 20D. The heating film layer 10D has uniformly arranged resistance wires 11D and at least one power interface 12D connected to the resistance wires 11D. The heating film layer 10D is disposed on a side of the heat sink 230D away from the wafer 300D to heat the wafer 300D through the heat sink 230D. The connection assembly 20D includes at least one first connection probe set 21D that passes through the lower sealing assembly 210D. One end of any first connection probe set 21D is in contact with a corresponding power interface 12D, and the other end passes through the lower sealing assembly 210D to contact the electrical component 226D. Thus, the electrical component 226D may supply power and heat the heating film layer 10D, which heats the wafer 300D on the heat sink 230D. The heating film layer 10D with evenly distributed resistance wires 11D may heat the wafer 300D evenly to avoid damages to the wafer 300D due to uneven heating. The yield of wafer 300D is increased. In addition, the heating device 100D of the present invention also includes the ceramic plate 50D. The ceramic plate 50D is located between the second thermal insulation element 40D and the heat sink 230D, and used to transfer the heat generated by the heating film layer 10D to the heat sink 230D. It avoids damaging the wafer 300D due to local overheating of the heating device 100D when the heating device 100D contacts the wafer 300D directly. The defective rate of the wafer 300D during wafer-level burn-in tests is reduced.

By now, those skilled in the art should appreciate that, although a number of exemplary embodiments of the present invention have been shown and described in detail herein, without departing from the spirit and scope of the present invention, many other variations or modifications consistent with the principles of the present invention can still be directly determined or deduced from the disclosure of the present invention. Accordingly, the scope of the present invention should be understood and deemed to cover all such other variations or modifications.

1. A wafer-level burn-in test device comprising:
a wafer-level burn-in test fixture including a cover plate assembly, a lower sealing assembly, a heat sink, and a heating device, wherein the heat sink is used to carry a wafer, the cover plate assembly includes a first PCB and a test probe holder connected to the first PCB, the lower sealing assembly includes a lower sealing cover, the lower sealing cover is connected with the cover plate assembly to form a test chamber, the heat sink and the heating device are disposed in the test chamber, and the heating device is disposed between the lower sealing cover and the heat sink; and
a lifting structure, wherein the lifting structure is configured to extend up and down in a controlled manner, the lifting structure abuts the wafer-level burn-in test fixture in a movable manner to drive the lower sealing assembly to move upward and connect with the cover plate assembly to form the testing chamber.

2. The device according to claim 1, wherein the lifting structure comprises:
a lifting component and an electrical component, the electrical component is located at a free end of the lifting component, the electrical component is connected to the lower sealing assembly in a movable manner, and the electrical component is configured to power the heating device and the heat sink for performing wafer-level burn-in testing on the wafer.

3. The device according to claim 2, wherein the heating device comprises:
a heating film layer including uniformly arranged resistance wires and at least one power interface connected to the resistance wires; and
at least one first connection probe set passing through the lower sealing cover, one end of each first connection probe set is in contact with one of the at least one power interface, another end of each first connection probe set is in contact with the electrical component for the electrical component to power the heating film layer and heat the wafer on the heat sink.

4. The device according to claim 3, wherein the electrical component comprises:
a second PCB connected to an external circuit, a top of the second PCB is provided with at least one first Pad position, each first Pad position is arranged corresponding to one of the at least first connection probe set, so that the external circuit powers the heating device through the second PCB when one of the at least one first Pad position is in contact with one of the least one first connection probe set for a heating test of the wafer.

5. The device according to claim 4, wherein the lower sealing cover is provided with at least one second connection probe set in contact with the heat sink, a top of the second PCB is further provided with at least one second Pad position, each second Pad position is arranged corresponding to one of the at least one second connection probe set, the external circuit powers the heat sink through the second PCB for powering the wafer for testing when the at least one second Pad position contacts a corresponding second connection probe set, a bottom of the lower sealing cover is provided with a plurality of first air holes, the second PCB is provided with a plurality of second air holes, each second air hole corresponds to one of the plurality of first air holes, the electrical component further comprises:
an adapter plate disposed below the second PCB, the adapter plate has an air channel connected to the plurality of second air holes for vacuuming the lower sealing cover through an external air path and via the air channel, the plurality of second air holes, and the plurality of first air holes for sucking the heat sink and the wafer.

6. The device according to claim 1, wherein the first PCB comprises:
a first interface set; and
a second interface set, wherein the test probe holder includes a plurality of test probes, the first interface set is provided on a first side of the first PCB facing the lower sealing assembly, an end of any test probe is connected to a corresponding first interface included in the first interface set and another end of any test probe is connected to the wafer for performing wafer-level burn-in testing on the wafer, the second interface set is provided on any one of a plurality of second sides of the first PCB except the first side, the wafer-level burn-in test fixture further includes:
a plurality of connectors mounted on the plurality of second sides of the first PCB, any connector is connected to a corresponding second interface included in the second interface set, any connector is connected to an external test device through a wire harness for performing wafer-level burn-in testing on the wafer.

7. The device according to claim 1, further comprising:
a mounting bracket, wherein the mounting bracket includes:
a bottom plate assembly;
a support platform used for supporting the lower sealing assembly; and
a pair of first glide grooves connected to the bottom plate assembly, wherein any first glide groove extends along a horizontal direction, two ends of the support platform are respectively connected to a corresponding first glide groove in a gliding manner, the lower sealing assembly is driven by the support platform and moves along an extension direction of one of the pair of first glide grooves, the lower sealing assembly slides along one of the pair of first glide grooves to go outside the mounting bracket when the wafer is loaded or unloaded, the lower sealing assembly is retracted in the mounting bracket along the one of the pair of first glide grooves after wafer loading or unloading is completed, and the mounting bracket further comprises:
a top plate assembly connected to the bottom plate assembly via a plurality of pillars; and
a pair of second glide grooves connected with the top plate assembly, any second glide groove extending in a horizontal direction, and two ends of the cover plate assembly being connected to a corresponding second glide groove in a gliding manner, respectively.

8. (canceled)

9. The device according to claim 1, further comprising:
a mounting bracket including a top plate assembly and a bottom plate assembly, the top plate assembly and the bottom plate assembly being connected through a pillar, the wafer-level burn-in test fixture being disposed below the top plate assembly and connected to the top plate assembly, and the lifting structure being installed on the bottom plate assembly; and
a floating structure provided at the top plate assembly, the floating structure configured to float when the cover plate assembly is pressed by the lower sealing cover to avoid deformation of the cover plate assembly.

10. The device according to claim 9, wherein the top plate assembly comprises:
an upper cover plate; and
a lower cover plate, the lower cover plate including a limiting groove, and the floating structure comprising:
a floating plate arranged on a top of the cover plate assembly and at the limit groove, and the floating plate protruding from a bottom of the lower cover plate; and
an extending component connected to the upper cover plate, wherein a bottom of the extending component connects or abuts the floating plate to cause the floating plate to move upward when the floating plate is pressed by the cover plate assembly, the floating plate is circular and arranged opposite to the test probe holder, a size of the floating plate is larger than a size of the test probe holder and smaller than a size of the lower sealing cover, a bottom of the upper cover plate is provided with at least one first mounting groove, a top of the floating plate is provided with at least one second mounting groove, and the extending component comprises:
at least one elastic member, wherein each elastic member is disposed in the first mounting groove and the second mounting groove correspondingly, and when the extending component comprises a plurality of elastic members, the plurality of elastic members is evenly arranged on the top of the floating plate.

11. (canceled)

12. (canceled)

13. The device according to claim 9, wherein the lifting structure comprises:
an electrical component including a second PCB, a top of the second PCB having a Pad position for powering the heating device and the heat sink for conducting wafer-level burn-in testing of the wafer; and
a lifting component, wherein the electrical component is located at a free end of the lifting component, the lifting component is used to drive the electrical component to move upward so that the Pad position cooperates with the lower sealing cover and to drive the lower sealing cover to move upward until the lower sealing cover is connected with the cover plate assembly to form the test chamber, and the lifting component comprises:
a plurality of turbine shafts connected to the electrical component, respectively; and
a motor connected to the plurality of turbine shafts to drive the plurality of turbine shafts to drive the electrical component to rise and fall.

14. (canceled)

15. A wafer-level burn-in test system, comprising:
a wafer loading and unloading device;
at least one test apparatus; and
at least one wafer-level burn-in test device, wherein the wafer loading and unloading device is used to place a wafer in a corresponding wafer-level burn-in test device to perform wafer-level burn-in testing, any wafer-level burn-in test device is connected with a corresponding test apparatus for wafer-level burn-in testing, the at least one wafer-level burn-in test device comprises:
a wafer-level burn-in test fixture including a cover plate assembly, a lower sealing assembly, a heat sink, and a heating device, wherein the heat sink is used to carry the wafer, the cover plate assembly includes a first PCB and a test probe holder connected to the first PCB, the lower sealing assembly includes a lower sealing cover, the lower sealing cover is connected with the cover plate assembly to form a test chamber, the heat sink and the heating device are disposed in the test chamber, and the heating device is disposed between the lower sealing cover and the heat sink; and
a lifting structure, wherein the lifting structure is configured to extend up and down in a controlled manner, the lifting structure abuts the wafer-level burn-in test fixture in a movable manner with to drive the lower sealing assembly to move upward and connect with the cover plate assembly to form the testing chamber.

16. (canceled)

17. A wafer-level burn-in test fixture, comprising:
a cover plate assembly; and
a lower sealing assembly, the cover plate assembly and lower sealing assembly being connected to form a test chamber for accommodating a wafer.

18. The fixture according to claim 17, wherein the cover plate assembly includes:
a PCB including a first area and a second area, wherein the first area and the second area are respectively located on different sides of the PCB, and any first contact point provided in the first area is electrically connected to a corresponding second contact point provided in the second area;
a test probe holder at a bottom of the PCB and connected to the PCB, wherein the test probe holder includes a plurality of test probes, an end of any test probe is in contact with a corresponding first contact point, and another end of any test probe is in contact with the wafer to perform wafer-level burn-in testing on the wafer; and
at least one connector mounted in the second area of the PCB, wherein any connector is connected to a corresponding second contact point, and any connector is connected to an external test device through a wire harness for performing wafer-level burn-in testing on the wafer.

19. The fixture according to claim 18, wherein the cover plate assembly further comprises:
a plurality of connectors arranged in an array on the PCB, wherein the test probe holder is circular, and the fixture further comprises:
a connection assembly in a shape of a ring and connected to the PCB, wherein the connecting assembly is arranged around an outer periphery of the test probe holder and connected to the test probe holder, an edge of the test probe holder is provided with at least one groove, the connecting assembly includes a support portion for supporting the test probe holder, the support portion is provided with at least one positioning post, each positioning post is arranged corresponding to one of the at least one groove to position the test probe holder, and a groove opening is arranged toward a corresponding one of the at least one positioning post.

20. The fixture according to claim 19, further comprising:
a round upper sealing cover located on a top of the PCB; and
a plurality of load-bearing components spaced apart along a circumferential direction of the upper sealing cover, each load-bearing component including:
a load-bearing column passing through the PCB and connected to the upper sealing cover, wherein the load-bearing column protrudes from a bottom surface of the PCB, and a height of the load-bearing column protruding from the bottom surface of the PCB is a value in a range of 0.1 mm˜0.2 mm; and
at least a sleeve sleeving around the load-bearing column to adjust the height of the load-bearing column protruding from the bottom surface of the PCB.

21. The fixture according to claim 18, further comprising:
a heat dissipation component mounted on the PCB, the heat dissipation component located between the first area and the second area and used to isolate heat generated in the first area.

22. The fixture according to claim 20, further comprising:
a structural member located on the top of the PCB and connected to the upper sealing cover; and
a plurality of reinforcement members on the top of the PCB and respectively provided on a peripheral side of the structural member, an edge of the PCB, and the second area.

23. The fixture according to claim 17, further comprising:
a hest sink for carrying the wafer; and
a heating device, wherein the heat sink and the heating device are in the test chamber, the heat sink is stacked above the heating device, the heating device is electrically connected to an electrical component located below the lower sealing assembly, and the heating device includes:
a heating film layer including uniformly arranged resistance wires and at least one power interface connected to the resistance wires, the heating film layer disposed on a side of the heat sink away from the wafer to heat the wafer through the heat sink; and
a connection assembly including at least one first connection probe set passing through the lower sealing assembly, wherein an end of any first connection probe set is in contact with a corresponding power interface, and another end of any first connection probe set passes through the lower sealing assembly and contacts with the electrical component for the electrical component to supply power and heat the heating film layer.

24. The fixture according to claim 23, wherein the heating film layer includes a mica heating sheet or a ceramic heating sheet, the fixture further comprises:
a first thermal insulation element located below the heat sink, wherein the heating film layer and the first thermal insulation element are integrally arranged, the heating film layer is located on a side of the first thermal insulation element close to the heat sink, the first thermal insulation element is provided with a first through hole corresponding to the at least one power interface, so that any first connection probe set passes through the first through hole to contact the at least one power interface;
a second thermal insulation element located on a side of the first thermal insulation element away from the heat sink, wherein the second thermal insulation element has a second through hole corresponding to the first through hole, and any first connection probe set passes through the first through hole and the second through hole to contact the at least one power interface; and
a ceramic plate located between the heating film layer and the heat sink and used to transfer heat generated by the heating film layer to the heat sink.

25. (canceled)

26. The fixture according to claim 23, further comprising:
at least one temperature sensor disposed at the heating film layer for detecting temperature of the heating film layer; and
at least one second connection probe set, wherein any second connection probe set corresponds to one of the at least one temperature sensor and passes through the lower sealing assembly, an end of one of the at least one second connection probe set is in contact with the at least one temperature sensor, and another end of the one of the at least one second connection probe set is in contact with a lifting structure.
